(19) United States
(12) Patent Application Publication
(10) Pub. No.: US 2025/0359307 A1
(43) Pub. Date: Nov. 20, 2025

(54) GUARD RING STRUCTURE AND METHOD FORMING SAME

(71) Applicant: Taiwan Semiconductor Manufacturing Company, Ltd., Hsin-Chu (TW)

(72) Inventor: I-Shan Huang, Tainan City (TW)

(21) Appl. No.: 19/282,729

(22) Filed: Jul. 28, 2025

Related U.S. Application Data
(63) Continuation of application No. 18/301,524, filed on Apr. 17, 2023.
(60) Provisional application No. 63/373,965, filed on Aug. 30, 2022.

(51) Int. Cl. H10D 84/83; H10D 84/01; H10D 84/03

(52) U.S. Cl. CPC H10D 84/834; H10D 84/014; H10D 84/0151; H10D 84/0158; H10D 84/038

(57) ABSTRACT

The present disclosure provides a method of manufacturing a semiconductor device. The method includes forming first fins in a first region of the semiconductor device, second fins in a second region of the semiconductor device, third fins in a third region of the semiconductor device, the second region encircling the first region, the third region encircling the second region. The method further includes forming first gate stacks over the first fins, second gate stacks over the second fins, and third gate stacks over the third fins, forming a mask layer covering the first region and the second region, performing an etching process to remove at least a portion of the third gate stacks, depositing a metal-containing material to replace the removed portion of the third gate stacks, and performing a planarization process to expose the first and second gate stacks.

### PRIORITY DATA

This is a continuation application of U.S. patent application Ser. No. 18/301,524, filed Apr. 17, 2023, which claims benefit of U.S. Provisional Patent Application No. 63/373,965, filed Aug. 30, 2022, each of which is incorporated herein by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, modern day ICs include millions or billions of transistors formed on a semiconductor substrate (e.g., silicon). ICs may use many different types of transistors, depending on applications of an IC. In recent years, the increasing market for cellular and RF (radio frequency) devices has resulted in a significant increase in the use of RF transistors. As the IC industry progresses to advanced technologies with smaller feature sizes, such as 7 nm, 5 nm, and 3 nm, the miniaturization process has resulted in various developments in IC designs that integrate RF transistors and logic transistors. The integrated circuit structures face various challenges including noise coupling, shorting, leakage, routing resistance, alignment margins, layout flexibility, and packing density. Therefore, there is a need for a structure and method for transistors to address these concerns for enhanced circuit performance and reliability.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a top view of an integrated circuit (IC) structure constructed according to various aspects of the present disclosure.

FIG. 2 is a cross-sectional view of the IC structure of FIG. 1, constructed according to various aspects of the present disclosure.

FIGS. 3, 4, 5, 6, 7, 8, 9, 10, 11, 12, 13, 14, 15, 16, 17, 18, 19, 20, and 21 illustrate perspective and cross-sectional views of intermediate stages in the formation of an IC structure according to various aspects of the present disclosure.

FIG. 22 illustrates a layout of an IC structure having one or more guard rings surrounding an RF circuit region according to various aspects of the present disclosure.

FIGS. 23, 24, 25, 26, 27, 28, 29, 30, and 31 illustrate cross-sectional views of intermediate stages in the formation of the IC structure of FIG. 22 according to various aspects of the present disclosure.

FIGS. 32 and 33 illustrate alternative layouts of an IC structure having one or more guard rings surrounding an RF circuit region according to various aspects of the present disclosure.

FIGS. 34A, 34B, 34C, and 34D illustrate some transistor structures that can be used as logic transistors and RF transistors devices according to various aspects of the present disclosure.

FIG. 35 illustrates a process flow for forming an IC structure that includes logic circuit regions and RF circuit regions according to various aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

This present disclosure is generally related to a semiconductor circuit structure having field-effect transistors (FETs) and the fabrication process thereof, and more particularly to a semiconductor circuit structure that includes a combination of a first type of transistors and a second type of transistors with one or more moat-like guard rings encircling the first type of transistors for separation from the second type of transistors. In accordance with some embodiments of the present disclosure, the first type of transistors are transistors for radio frequency (RF) applications (also termed as RF transistors) and the second type of transistors are transistors for logic applications (also termed as logic transistors). RF transistors work at high frequency band such as in the range between about 100 kHz and about 300 GHz, or between about 1 GHz and about 300 GHz. Logic transistors work at a frequency band that is lower than the RF transistors. Those of ordinary skill in the art should appreciate that other types of transistors other than RF transistors and/or logic transistors, such as a combination of a first type of transistors for memory applications and a second type of transistors for input/output (I/O) applications, may readily use the present disclosure as a basis for designing or modifying other processes and structures for carrying out the same purposes and/or achieving the same advantages of the embodiments introduced herein.

Further, the present disclosure provides various embodiments of integrated circuit (IC) formed on a semiconductor substrate. The integrated circuit has a design layout that may be incorporated with various standard cells. The standard cells are predesigned IC structure to be repeatedly used in individual IC designs. Effective IC design layouts include various predesigned standard cells and predefined rules of placing those standard cells for enhanced circuit performing and reduced circuit areas. In accordance with embodiments, the formation of fin field-effect (FinFET) transistors is used as an example to explain the concept of the present disclosure. Other types of transistors such as planar transistors, nano-sheet or nano wire transistors, gate-all-around (GAA) transistors, or the like, may also adopt the concept of the present disclosure. The intermediate stages of forming the FinFET transistors are illustrated in accordance with some embodiments. Some variations of some embodiments are discussed. Throughout the various views and illustrative embodiments, like reference numbers are used to designate like elements. Although method embodiments may be discussed as being performed in a particular order, other method embodiments may be performed in any logical order.

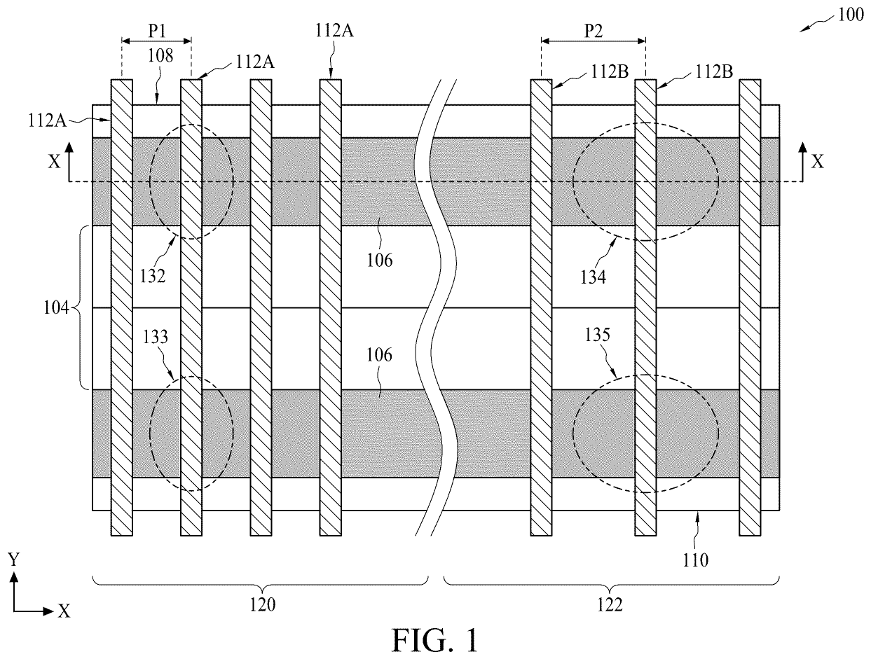

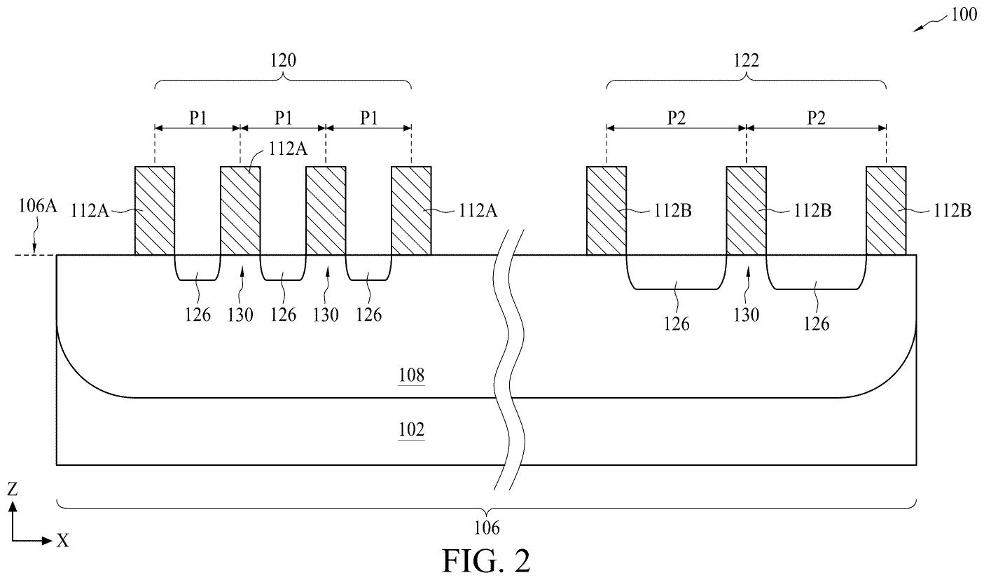

Reference is now made to FIGS. 1 and 2, collectively. FIG. 1 is a top view of a semiconductor structure (or semiconductor device) 100 and FIG. 2 is a cross-sectional view of the semiconductor structure 100 along the dashed line X-X of FIG. 1, constructed according to various aspects of the present disclosure in one embodiment. In some embodiments, the semiconductor structure 100 is formed on flat active regions and includes field effect transistors (FETs). In some embodiments, the semiconductor structure 100 is formed on fin active regions and includes FinFETs. In some embodiments, the semiconductor structure 100 includes FETs formed on vertically stacked channels (also referred to as GAA transistors). With the semiconductor structure 100 as an example for illustration, an IC structure and a method making the same are collectively described.

In various embodiments, the semiconductor structure 100 includes various circuit modules integrated on a same substrate. Those circuit modules (or simply circuits) may have different functions or different circuit characteristics. Those circuit modules are placed on different circuit regions of the substrate, either adjacent or distanced, or with different surrounding environments. For example, the semiconductor structure 100 includes a first circuit region 120 and a second circuit region 122 disposed on a semiconductor substrate (or simply substrate) 102. The semiconductor structure 100 may include additional circuit regions, similar to or different from the first and second circuit regions. For example, the semiconductor structure 100 includes other logic circuit region(s), other RF circuit region(s), other circuit regions, such as memory regions, imaging sensor regions, analog circuit regions, or a combination thereof. In some embodiments, the first circuit formed in the first circuit region 120 is a logic circuit and the second circuit formed in the second circuit region 122 is a radio frequency (RF) circuit. An RF circuit usually requires high-frequency and high speed, and accordingly less parasitic capacitance. In some embodiments, the IC structure further includes a third circuit formed in a third circuit region, in which the third circuit is a memory circuit including various memory devices, such as static random-access memory (SRAM) cells, configured in an array.

Those circuit regions may include one or more standard cell placed to the IC layout by predefined rules. Those standard cells are repeatedly used in integrated circuit designs and therefore predesigned according to manufacturing technologies and saved in a standard cell library. IC designers could retrieve those standard cells, incorporate in their IC designs, and place into the IC layout according to the predefined placing rules. For examples, a logic standard cell may include various basic circuit devices, such as inverter, AND, NAND, OR, XOR, and NOR, flip-flop circuit, latch or a combination thereof, which are popular in digital circuit design for applications, such as central processing unit (CPU), graphic processing unit (GPU), and system on chip (SOC) chip designs.

The substrate 102 includes silicon. Alternatively, the substrate 102 may include an elementary semiconductor, such as silicon or germanium in a crystalline structure; a compound semiconductor, such as silicon germanium, silicon carbide, gallium arsenic, gallium phosphide, indium phosphide, indium arsenide, and/or indium antimonide; or combinations thereof. Possible substrates 102 also include a silicon-on-insulator (SOI) substrate. SOI substrates are fabricated using separation by implantation of oxygen (SIMOX), wafer bonding, and/or other suitable methods.

The substrate 102 also includes various isolation features 104, such as isolation features formed on the substrate 102 and thereby defining various active regions 106 on the substrate 102. The isolation features 104 utilize isolation technology, such as shallow trench isolation (STI), to define and electrically isolate the various active regions. Each active region 106 is surrounded by a continuous isolation feature such that it is separated from other adjacent active regions. The isolation features 104 include silicon oxide, silicon nitride, silicon oxynitride, other suitable dielectric materials, or combinations thereof. The isolation features 104 are formed by any suitable process. As one example, forming STI features includes a lithography process to expose a portion of the substrate, etching a trench in the exposed portion of the substrate (for example, by using a dry etching and/or wet etching), filling the trench (for example, by using a chemical vapor deposition process) with one or more dielectric materials, and planarizing the substrate and removing excessive portions of the dielectric material(s) by a polishing process, such as a chemical mechanical polishing (CMP) process. In some examples, the filled trench may have a multi-layer structure, such as a thermal oxide liner layer and filling layer(s) of silicon nitride or silicon oxide.

The active region 106 is a region with a semiconductor surface wherein various doped features are formed and configured to one or more device, such as a diode, a transistor, and/or other suitable devices. The active region 106 may include a semiconductor material similar to that (such as silicon) of the bulk semiconductor material of the substrate 102 or different semiconductor material, such as silicon germanium (SiGe), silicon carbide (SiC), or multiple semiconductor material layers (such as alternative silicon and silicon germanium layers) formed on the substrate 102 by epitaxial growth, for performance enhancement, such as strain effect to increase carrier mobility.

In some embodiments, the active region 106 is three-dimensional, such as a fin active region extended above the isolation feature. The fin active region 106 is extruded above the isolation features 104 from the substrate 102 and has a three-dimensional profile for more effective coupling between the channel and the gate electrode of a FET. Particularly, the substrate 102 has a top surface and the fin active region 106 has a top surface 106A that is above the top surface of the substrate 102. The fin active region 106 may be formed by selective etching to recess the isolation features, or selective epitaxial growth to grow active regions with a semiconductor same or different from that of the substrate 102, or a combination thereof.

The substrate 102 further includes various doped features, such as n-type doped wells, p-type doped wells, source and drain features, other doped features, or a combination thereof configured to form various devices or components of the devices, such as source and drain features of a field-effect transistor. In the present example illustrated in FIG. 1, the semiconductor structure 100 includes a negatively doped well (also referred to as N well) 108 and a positively doped well (also referred to as P well) 110. The N well 108 includes negative dopant, such as phosphorus. And the P well 110 includes positive dopant, such as boron. The N well 108 and the P well 110 are formed by suitable technologies, such as ion implantation, diffusion or a combination thereof. In the present embodiment, one active region 106 is formed in the N well 108 and another active region 106 is formed in the P well 110.

The semiconductor structure 100 further includes various gates stacks (or simply gates) 112 having elongated shape oriented in a first direction (Y-direction). In the present embodiment, X and Y directions are orthogonal and define a top surface of the substrate 102. A gate stack includes a gate dielectric layer and a gate electrode. The gate stack is a feature of a FET and functions with other features, such as source/drain (S/D) features and a channel, wherein the channel is a portion of the active region directly underlying the gate stack; and the S/D features are in the active region and are disposed on two sides of the gate stack. In the present embodiments, the gate stacks in the first circuit region 120 and the second circuit region 122 are referred to as gate stacks 112A and 112B, respectively. It is noted that a gate stack should not be confused with a logic gate, such a NOR logic gate.

The semiconductor structure 100 may also include some dummy gate stacks disposed on the substrate 102. A dummy gate is not a functional gate. Instead, the dummy gate is disposed for other purpose, such as tuning the pattern density and/isolation. The dummy gate may have a similar structure as a functional gate 112. Alternatively, the dummy gate may have different structure or even be dielectric feature (also referred to as dielectric gate) that includes one or more dielectric material and function as an isolation feature, in some instances.

The dummy gates are similar to the gates 112 in term of formation. In some embodiments, the gates 112 and the dummy gates are collectively formed by a procedure, such as a gate-last process. In furtherance of the embodiments, initial dummy gates are first formed by deposition and patterning, in which the patterning further includes lithography process and etching. Afterward, a subset of the initial dummy gates is replaced to form gates 112 by depositing a gate dielectric layer and a gate electrode while the rest of the initial dummy gates are replaced to form dielectric gates by depositing dielectric material(s). Furthermore, the dummy gate is disposed and configured differently and therefore functions differently. In the depicted embodiment, some dielectric gates are placed on the border regions between circuit modules or borders of the standard cells to function as isolation to separate one standard cell to an adjacent standard cell, and some dielectric gates are placed inside the standard cells or inside a circuit module in a circuit region for one or more considerations, such as isolation between the adjacent FETs and adjust pattern density. Thus, the dummy gates provide isolation function between adjacent IC devices and additionally provides pattern density adjustment for improved fabrication, such as etching, deposition and CMP.

In the present embodiment, the semiconductor structure 100 includes the first circuit region 120 for logic circuits and the second circuit region 122 for RF circuits. The two circuit regions 120 and 122 may be placed next to each other or distance away separated by a dummy region that includes a plurality of dummy gates.

In the depicted embodiment, the semiconductor structure 100 includes the first active region 106 in the N well 108 and the second active region 106 in the P well 110. The gate 112A in the first circuit region 120 may extend continuously from the first active region 106 (in the N well 108) to the second active region 106 (in the P well 110) along the Y-direction. Similarly, the gate 112B in the second circuit region 122 may extend continuously from the first active region 106 (in the N well 108) to the second active region 106 (in the P well 110) along the Y-direction.

With source/drain regions 126 and a channel 130 formed for each transistor associated with a respective gate, a respective active region, and a respective circuit region, the first circuit region 120 includes one p-type FET (pFET) 132 in the N well 108 and one n-type FET (nFET) 133 in the P well 110; and the second circuit region 122 includes one pFET 134 in the N well 108 and one nFET 135 in the P well 110. In the present embodiment, the pFET 132, the nFET 133, and other FETs in the first circuit region 120 are integrated to form a functional circuit block, such as a logic circuit; and the pFET 134, the nFET 135, and other FETs in the second circuit region 122 are integrated to form another functional circuit block, such as an RF circuit.

FIGS. 1 and 2 provide an exemplary semiconductor structure 100 having the first circuit region 120 and the second circuit region 122 for illustration. However, it is understood that the semiconductor structure 100 may include additional circuit regions and some dummy regions (or filler regions) added in a various configuration. In some embodiments, various circuit regions are surrounded by respective dummy regions. For examples, depending on individual design, additional circuit regions and dummy regions may be added to the left edge, to the right edge, to the up edge, and/or to the down edge of FIG. 1 in a similar configuration. The IC structures in other figures, such as those discussed below, should be understood similarly.

Especially, the gate stacks 112A in the first circuit region 120 and the gate stacks 112B in the second circuit region 122 have different pitches. A pitch is defined as periodic distance of an array of gates, such as a center-to-center distance of two adjacent gates in the array of gates. In the present embodiment, the gate stacks 112A has a first pitch P1 and the gate stacks 112B has a second pitch P2 being greater than the first pitch P1. For example, the first pitch P1 is less than a reference pitch and the second pitch P2 is greater than the reference pitch. The reference pitch is determined according to fabrication technology and characteristics of the first and second transistors. In the depicted embodiment, the reference pitch may be around 100 nm. For example, the first pitch P1 is less than 100 nm and the second pitch P2 is greater than 100 nm. In some embodiments, the ratio P2/P1 is greater enough, such as greater than 1.5, to achieve the expected circuit performance enhancement with respective gate profiles. In some embodiments, the P2/P1 ranges between 1.2 and 2. The first pitch P1 and the second pitch P2 can be respectively tuned for respective circuit performance. Thus, the RF circuit in the second circuit region 122 can have a greater pitch, less parasitic capacitance, and high frequency performance; while the logic circuit in the first circuit region 120 can have a less pitch and higher packing density without degrading the overall circuit performance. Additionally, the gate stacks 112A and 112B may be different in gate pitch, gate dimensions, gate structure, gate profile, gate orientation, gate configuration, gate composition, gate environment, dummy gate design, or a combination thereof.

In the above example, only two circuit regions (120 and 122) are illustrated. However, the semiconductor structure 100 may include multiple circuit regions, each being designed for respective functions, such as a first circuit region for a logic circuit with a first gate pitch, a second circuit region for a RF circuit with a second gate pitch, a third circuit region for a memory circuit with a third gate pitch, a fourth circuit region for I/O devices with a fourth gate pitch, and etc. Those gate pitches are different from each other and individually tuned for respective circuit characteristics and performance enhancement. Furthermore, each circuit regions may include dummy gates surrounding the functional gates. The dummy gates are further tuned with different design (such as gate pitch, gate dimensions and gate groups) to compensate the pattern density such that the process defects are eliminated while the circuit performance is enhanced. The areas for the dummy gates are referred to as dummy areas and the areas for the functional gates are referred to as active device areas (or active circuit areas). Since the dummy gates in the dummy areas are not parts of the circuits and are designed to enhance the fabrication and circuit performance, and therefore have more freedoms for tuning, such as gate materials, gate pitches, gate dimensions, gate orientations and gate pattern density. Furthermore, placements and sizes of the dummy areas are also factors to be used for tuning process. For examples, a dummy area is to be placed next to an edge of a circuit region where the gate pattern density is relatively away from the average.

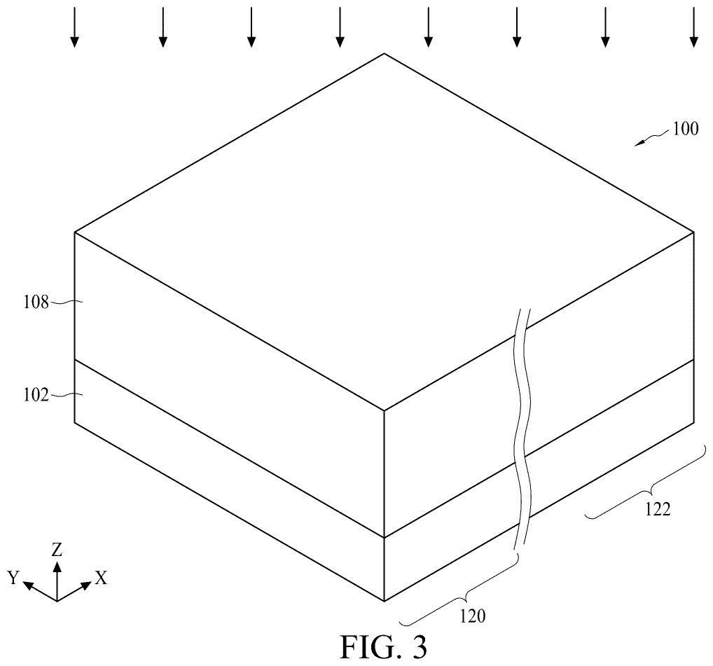

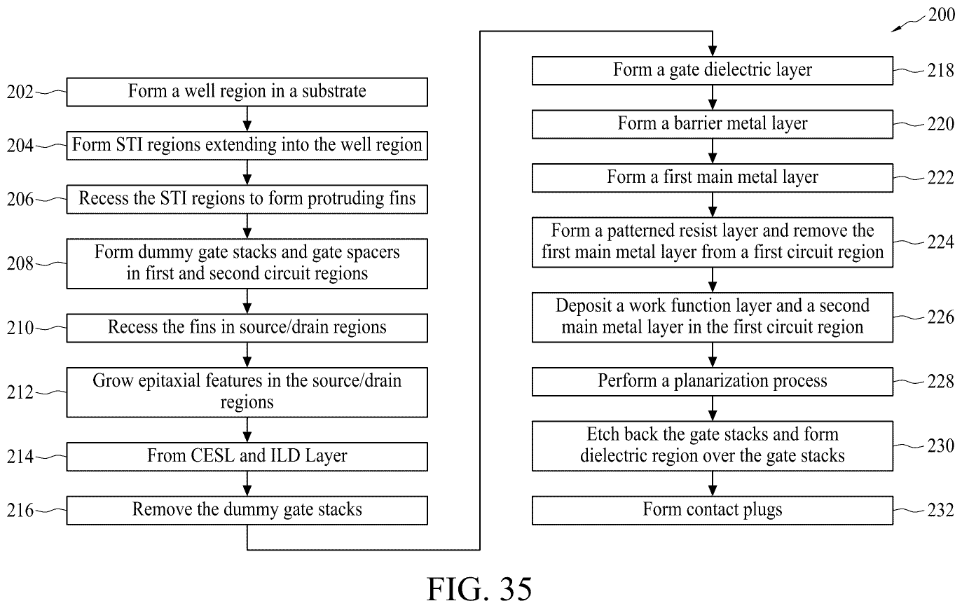

Reference is now made to FIGS. 3-21, which illustrate perspective views and cross-sectional views of intermediate stages in the formation of RF transistors and logic transistors in the semiconductor device 100 in FIGS. 1 and 2, in accordance with some embodiments of the present disclosure. The processes shown in these figures are also reflected schematically in the process flow 200 shown in FIG. 35.

Referring to FIG. 3, the substrate 102 is provided. The substrate 102 may be a semiconductor substrate, such as a bulk semiconductor substrate, a semiconductor-on-insulator (SOI) substrate, or the like, which may be doped (e.g., with a p-type or an n-type dopant) or undoped. The substrate 102 may be a part of a wafer, such as a silicon wafer. Generally, an SOI substrate is a layer of a semiconductor material formed on an insulator layer. The insulator layer may be, for example, a Buried Oxide (BOX) layer, a silicon oxide layer, or the like. The insulator layer is provided on a substrate, typically a silicon or glass substrate. Other substrates such as a multi-layered or gradient substrate may also be used. In some embodiments, the semiconductor material of the substrate 102 may include silicon; germanium; a compound semiconductor including carbon-doped silicon, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

Further referring to FIG. 3, a well region 108 is formed in the substrate 102. The respective process is illustrated as process 202 in the process flow 200 shown in FIG. 35. In accordance with some embodiments of the present disclosure, the well region 108 is an n-type well region formed through implanting an n-type impurity, which may be phosphorus, arsenic, antimony, or the like, into the substrate 102. In accordance with other embodiments of the present disclosure, the well region is a p-type well region formed through implanting a p-type impurity, which may be boron, indium, or the like, into the substrate 102. The resulting well region 108 may extend to the top surface of the substrate 102. The n-type or p-type impurity concentration may be equal to or less than 10¹⁸ cm⁻³, such as in a range between about 10¹⁷ cm⁻³ and about 10¹⁸ cm⁻³. The substrate 102 also includes a first circuit region 120 to form logic transistors and a second circuit region 122 to form RF transistors.

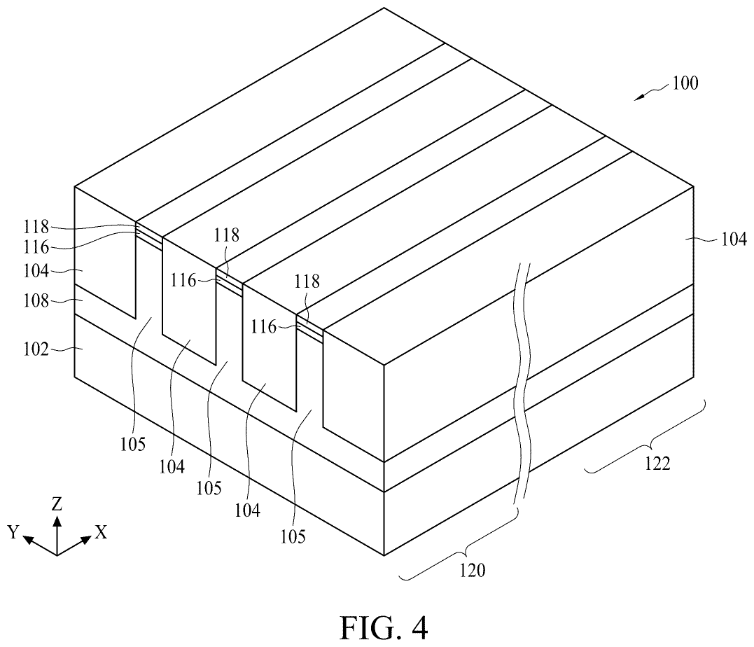

Referring to FIG. 4, isolation regions 104 are formed to extend from a top surface of the substrate 102 into the substrate 102. Isolation regions 104 are alternatively referred to as Shallow Trench Isolation (STI) regions. The respective process is illustrated as process 204 in the process flow 200 shown in FIG. 35. The portions of the substrate 102 between neighboring STI regions 104 are referred to as semiconductor strips 105. To form the STI regions 104, a pad oxide layer 116 and a hard mask layer 118 are formed on semiconductor the substrate 102, and are then patterned. The pad oxide layer 116 may be a thin film formed of silicon oxide. In accordance with some embodiments of the present disclosure, the pad oxide layer 116 is formed in a thermal oxidation process, wherein a top surface layer of the substrate 102 is oxidized. The pad oxide layer 116 acts as an adhesion layer between the substrate 102 and the hard mask layer 118. The pad oxide layer 116 may also act as an etch stop layer for etching the hard mask layer 118. In accordance with some embodiments of the present disclosure, the hard mask layer 118 is formed of silicon nitride, for example, using Low-Pressure Chemical Vapor Deposition (LPCVD). In accordance with other embodiments of the present disclosure, the hard mask layer 118 is formed by thermal nitridation of silicon, or Plasma Enhanced Chemical Vapor Deposition (PECVD). A photo resist (not shown) is formed on the hard mask layer 118 and is then patterned. The hard mask layer 118 is then patterned using the patterned photo resist as an etching mask to form the patterned hard mask layer 118 as shown in FIG. 4.

Next, the patterned hard mask layer 118 is used as an etching mask to etch the pad oxide layer 116 and the substrate 102, followed by filling the resulting trenches in the substrate 102 with a dielectric material(s). A planarization process such as a Chemical Mechanical Polish (CMP) process or a mechanical grinding process is performed to remove excessing portions of the dielectric materials, and the remaining portions of the dielectric materials(s) are the STI regions 104. The STI regions 104 may include a liner dielectric (not shown), which may be a thermal oxide formed through a thermal oxidation of a surface layer of the substrate 102. The liner dielectric may also be a deposited silicon oxide layer, silicon nitride layer, or the like formed using, for example, Atomic Layer Deposition (ALD), High-Density Plasma Chemical Vapor Deposition (HDPCVD), or Chemical Vapor Deposition (CVD). The STI regions 104 may also include a dielectric material over the liner oxide, wherein the dielectric material may be formed using Flowable Chemical Vapor Deposition (FCVD), spin-on coating, or the like. The dielectric material over the liner dielectric may include silicon oxide in accordance with some embodiments.

The top surfaces of the patterned hard mask layer 118 and the top surfaces of the STI regions 104 may be substantially level with each other. The semiconductor strips 105 are between neighboring STI regions 104. In accordance with some embodiments of the present disclosure, the semiconductor strips 105 are parts of the original substrate 102, and hence the material of the semiconductor strips 105 is the same as that of the substrate 102. In accordance with alternative embodiments of the present disclosure, the semiconductor strips 105 are replacement strips formed by etching the portions of the substrate 102 between the STI regions 104 to form recesses, and performing an epitaxy to regrow another semiconductor material in the recesses. Accordingly, the semiconductor strips 105 are formed of a semiconductor material different from that of the substrate 102. In accordance with some embodiments, the semiconductor strips 105 are formed of silicon germanium, silicon carbon, or a III-V compound semiconductor material. The patterned hard mask layer 118 is then removed.

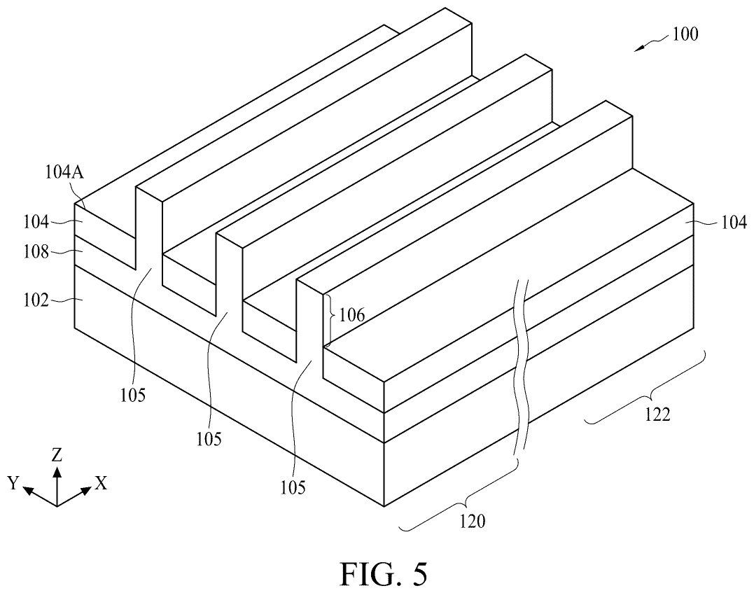

Referring to FIG. 5, the STI regions 104 are recessed, so that the top portions of semiconductor strips 105 protrude higher than the top surfaces 104A of the remaining portions of the STI regions 104 to form protruding fins 106. The respective process is illustrated as process 206 in the process flow 200 shown in FIG. 35. The pad oxide layer 116 and the patterned hard mask layer 118 are also removed. The etching may be performed using a dry etching process, wherein HF₃ and NH₃, for example, are used as the etching gases. During the etching process, plasma may be generated. Argon may also be included. In accordance with alternative embodiments of the present disclosure, the recessing of the STI regions 104 is performed using a wet etch process. The etching chemical may include HF, for example.

In above-illustrated embodiments, the fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins.

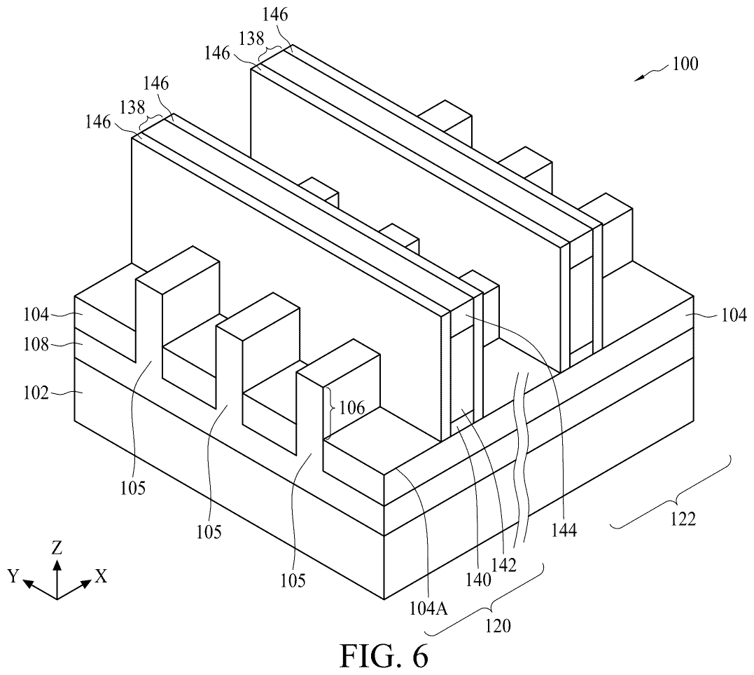

Referring to FIG. 6, dummy gate stacks 138 are formed to extend on the top surfaces and the sidewalls of (protruding) fins 106. The respective process is illustrated as process 208 in the process flow 200 shown in FIG. 35. The dummy gate stacks 138 may include dummy gate dielectrics 140 and dummy gate electrodes 142 over dummy gate dielectrics 140. The dummy gate dielectrics 140 may be formed of silicon oxide or like materials. The dummy gate electrodes 142 may be formed, for example, using polysilicon, and other materials may also be used. Each of the dummy gate stacks 138 may also include one (or a plurality of) hard mask layer 144 over the dummy gate electrodes 142. The hard mask layer 144 may be formed of silicon nitride, silicon oxide, silicon carbo-nitride, or multi-layers thereof. The dummy gate stacks 138 may cross over a single one or a plurality of protruding fins 106 and/or STI regions 104. The dummy gate stacks 138 also have lengthwise directions perpendicular to the lengthwise directions of the fins 106.

Next, the gate spacers 146 are formed on the sidewalls of the dummy gate stacks 138. The respective process is also shown as process 208 in the process flow 200 shown in FIG. 35. In accordance with some embodiments of the present disclosure, the gate spacers 146 are formed of a low-k dielectric material(s) such as porous silicon oxy-nitride, porous silicon carbo-nitride, porous silicon nitride, or the like, and may have a single-layer structure or a multi-layer structure including a plurality of dielectric layers. The dielectric constant (k value) of gate spacers 146 is lower than 3.8, and may be lower than about 3.0, for example, in the range between about 2.5 and about 3.0.

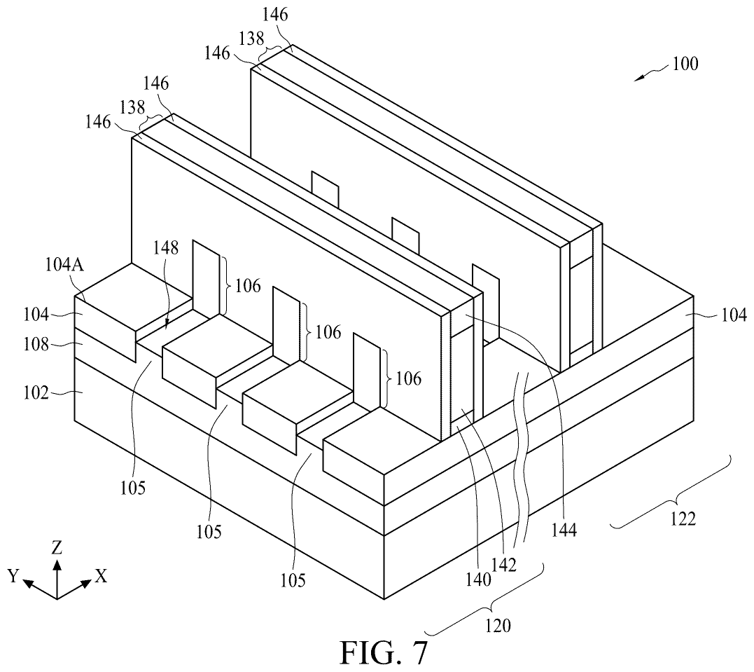

Referring to FIG. 7, an etching process is then performed to etch portions of the fins 106 that are not covered by the dummy gate stacks 138 and the gate spacers 146. The respective process is illustrated as process 210 in the process flow 200 shown in FIG. 35. The recessing may be anisotropic, and hence the portions of the fins 106 directly underlying the dummy gate stacks 138 and the gate spacers 146 are protected, and are not etched. The top surfaces of the recessed semiconductor strips 105 may be lower than the top surface 104A of the STI regions 104 in accordance with some embodiments. Recesses 148 are accordingly formed. The recesses 148 comprise portions located on the opposite sides of the dummy gate stacks 138, and portions between remaining portions of fins 106.

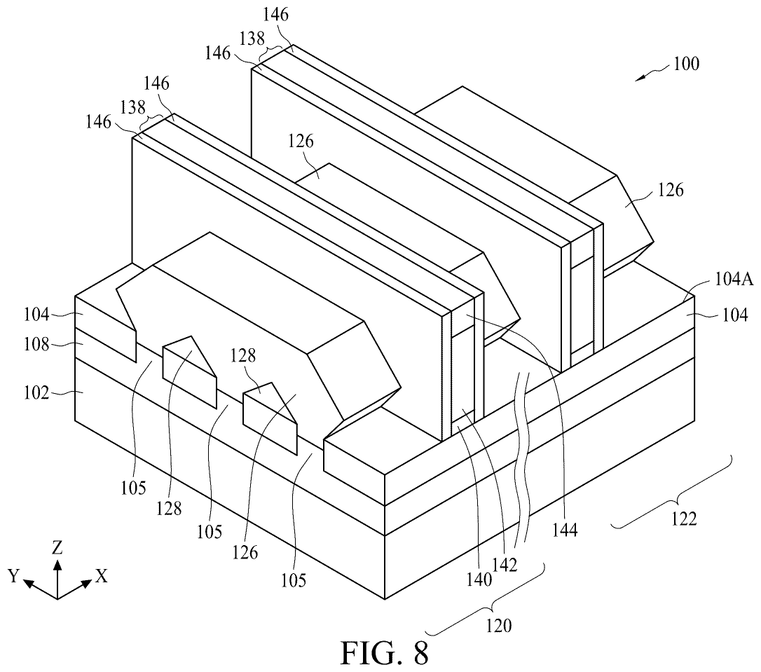

Referring to FIG. 8, epitaxy features (or referred to as source/drain features or source/drain regions) 126 are formed by selectively growing (through epitaxy) a semiconductor material in the recesses 148. The respective process is illustrated as process 212 in the process flow 200 shown in FIG. 35. For example, when the resulting FinFET is a p-type FinFET, boron doped silicon germanium (SiGeB), boron-doped silicon (SiB), or the like may be grown; when the resulting FinFET is an n-type FinFET, phosphorous doped silicon (SiP), arsenic-doped silicon (SiAs), or the like may be grown. In accordance with alternative embodiments of the present disclosure, the source/drain regions 126 comprise III-V compound semiconductors such as GaAs, InP, GaN, InGaAs, InAlAs, GaSb, AlSb, AlAs, AIP, GaP, combinations thereof, or multi-layers thereof. After the recesses 148 are filled with the source/drain regions 126, the further epitaxial growth of the source/drain regions 126 causes the source/drain regions 126 to expand horizontally, and facets may be formed. The further growth of the source/drain regions 126 may also cause neighboring source/drain regions 126 to merge with each other. Voids (air gaps) 128 may be generated. Source/drain region(s) may refer to a source or a drain, individually or collectively dependent upon the context.

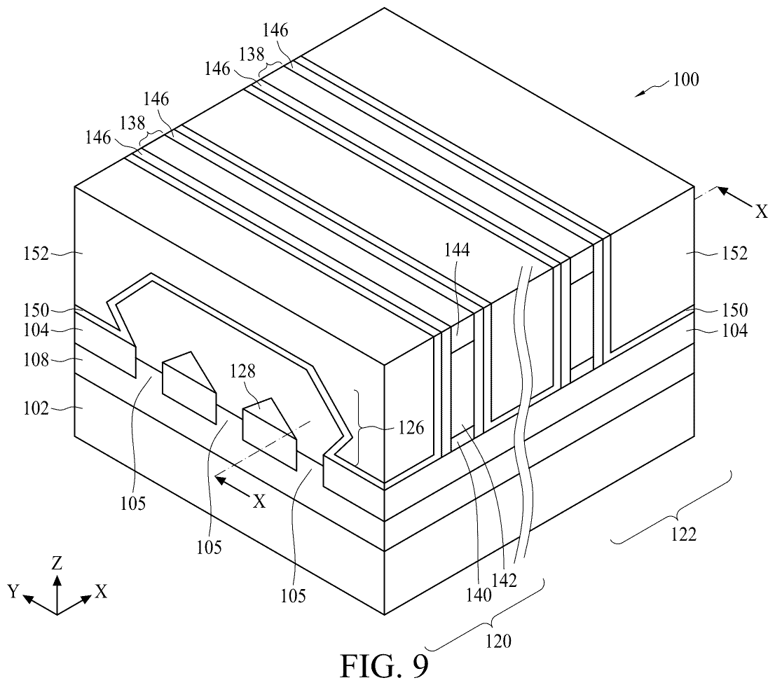

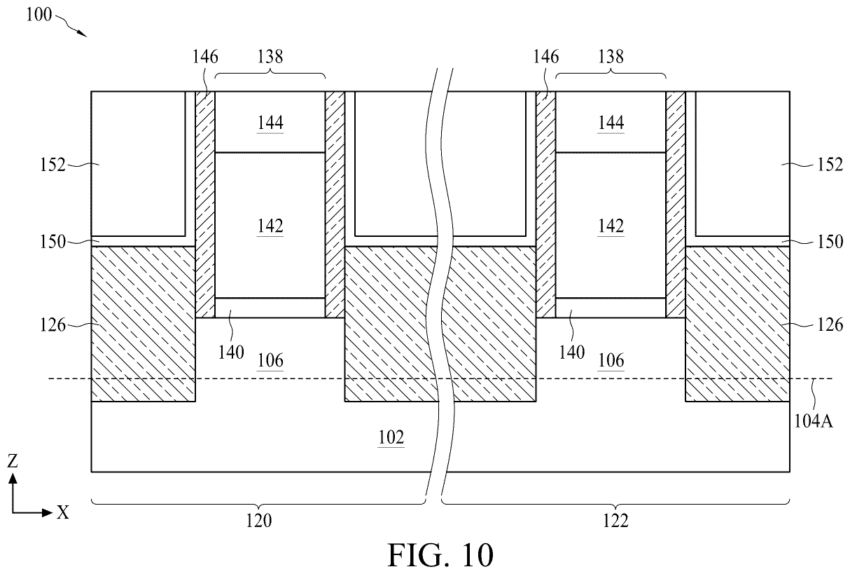

Referring to FIGS. 9 and 10, FIG. 9 illustrates a perspective view of the structure after the formation of a Contact Etch Stop Layer (CESL) 150 and an inter-layer dielectric (ILD) layer 152, and FIG. 10 illustrates a cross-sectional view along the line X-X in FIG. 9. The respective process is illustrated as process 214 in the process flow 200 shown in FIG. 35. The CESL 150 may be formed of silicon nitride, silicon oxide, silicon, carbo-nitride, or the like, and may be formed using CVD, ALD, or the like. The ILD layer 152 may include a dielectric material formed using, for example, FCVD, spin-on coating, CVD, or another deposition method. The ILD layer 152 may be formed of an oxygen-containing dielectric material, which may be a silicon-oxide based material such as silicon oxide, Phospho-Silicate Glass (PSG), Boro-Silicate Glass (BSG), Boron-Doped Phospho-Silicate Glass (BPSG), or the like. A planarization process such as a CMP process or a mechanical grinding process may be performed to level the top surfaces of the ILD layer 152, the dummy gate stacks 138, and the gate spacers 146 with each other. In FIG. 10, the level of the top surface 104A of the STI regions 104 are show, and fins 106 are higher than the top surface 104A.

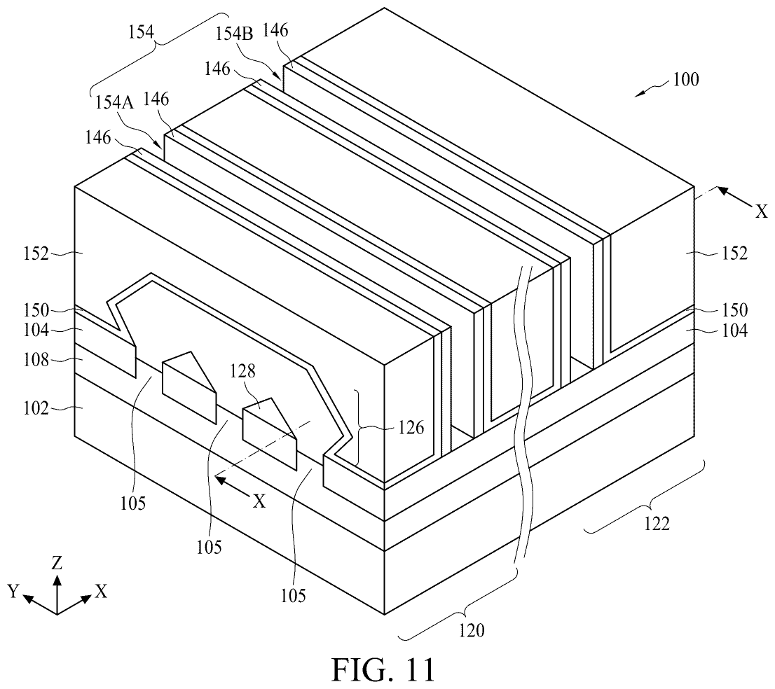

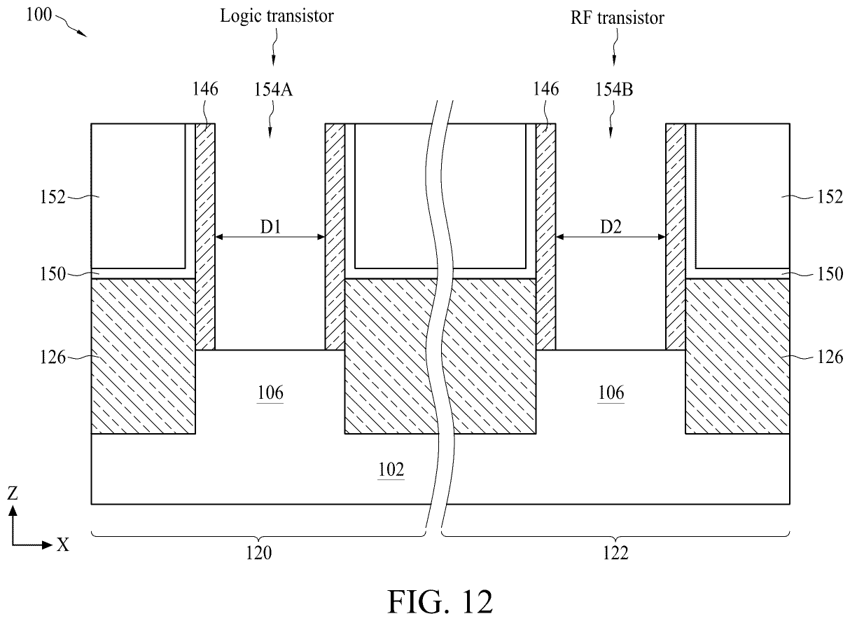

Referring to FIGS. 11 and 12, FIG. 11 illustrates a perspective view of the structure after the dummy gate stacks 138 are removed, and FIG. 12 illustrates a cross-sectional view along the line X-X in FIG. 11. In some embodiments, the removal of the dummy gate stacks 138 include one or more etching processes that remove the hard mask 144, dummy gate electrode 142, and dummy gate dielectric 140 in the dummy gate stacks 138, resulting in gate trenches 154. For example, the removal of the dummy gate stacks 138 may be performed using a selective etch process such as a selective wet etch, a selective dry etch, or a combination thereof. The respective process is illustrated as process 216 in the process flow 200 shown in FIG. 35. The top surfaces and the sidewalls of the fins 106 are exposed in the gate trenches 154. The gate trenches 154 in the first circuit region 120 for logic circuits are denoted as the gate trenches 154A, and the gate trenches in the second circuit region 122 for RF circuits are denoted as the gate trenches 154B. Due to the different applications of logic transistors and RF transistors, the gate trenches 154A and 154B may have different dimensions. Accordingly, the subsequently formed gate stacked in the gate trenches 154A and 154B may have different dimensions. For example, the gate trench 154A in the first circuit region 120 for logic circuits have a first width D1 (also the gate width of the logic transistor formed in the gate trench 154A) less than a reference dimension (such as 40 nm in some examples), and the gate trench 154B in the second circuit region 122 for RF circuits have a second width D2 (also the gate width of the RF transistor formed in the gate trench 154B) larger than the reference dimension. In some embodiments, the ratio D2/D1 ranges between 1.2 and 3. In some embodiments, the ratio D2/D1 is greater than 2.

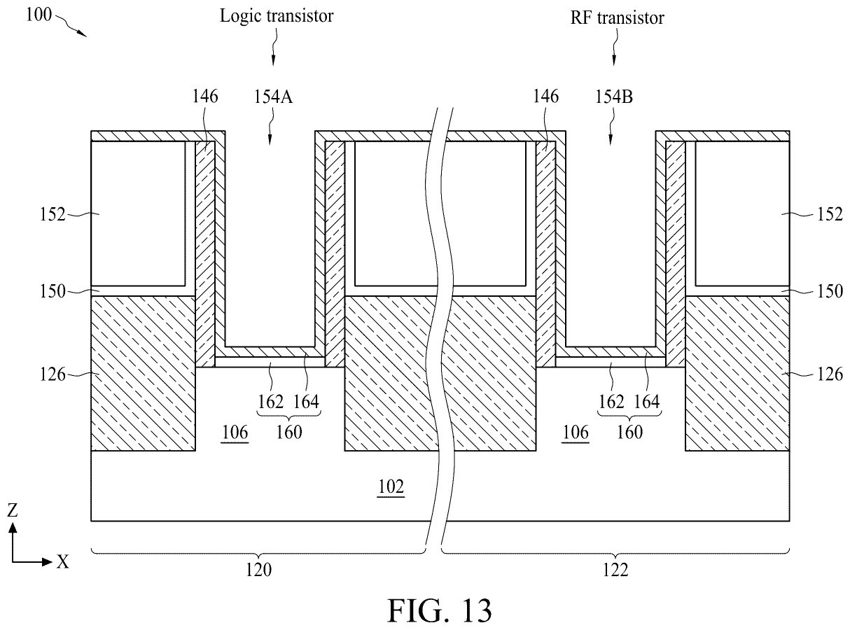

Referring to FIG. 13, a gate dielectric layer 160 is formed in both the gate trenches 154A and 154B and contacts the top surface and the sidewalls of the fins 106. The respective process is illustrated as process 218 in the process flow 200 shown in FIG. 35. In accordance with some embodiments of the present disclosure, the gate dielectric layer 160 includes an interfacial layer (IL) 162, which is formed on the exposed top and sidewall surfaces of the fins 106. The IL 162 may include an oxide layer such as a silicon oxide layer, which is formed through the thermal oxidation of the fins 106, a chemical oxidation process, or a deposition process. The gate dielectric layer 160 may also include a high-k dielectric layer 164 over the IL 162. The high-k dielectric layer 164 may be formed of a high-k dielectric material comprising Si, Hf, Zr, Pb, Sb, La, or the like. For example, the high-k dielectric layer 164 may be formed of or comprise hafnium oxide, lanthanum oxide, aluminum oxide, zirconium oxide, combinations thereof, multi-layers thereof, or the like. The thickness of the high-k dielectric layer 164 may be in the range between about 10 Å and about 40 Å. The dielectric constant (k-value) of the high-k dielectric material is higher than 3.9, and may be higher than about 7.0, or higher. The high-k dielectric layer 164 is overlying, and may contact, the respective underlying IL 162. The high-k dielectric layer 164 is formed as a conformal layer, and extends on the sidewalls of the fins 106 and the top surface and the sidewalls of the gate spacers 146. In accordance with some embodiments of the present disclosure, the high-k dielectric layer 164 is formed using ALD, CVD, or the like.

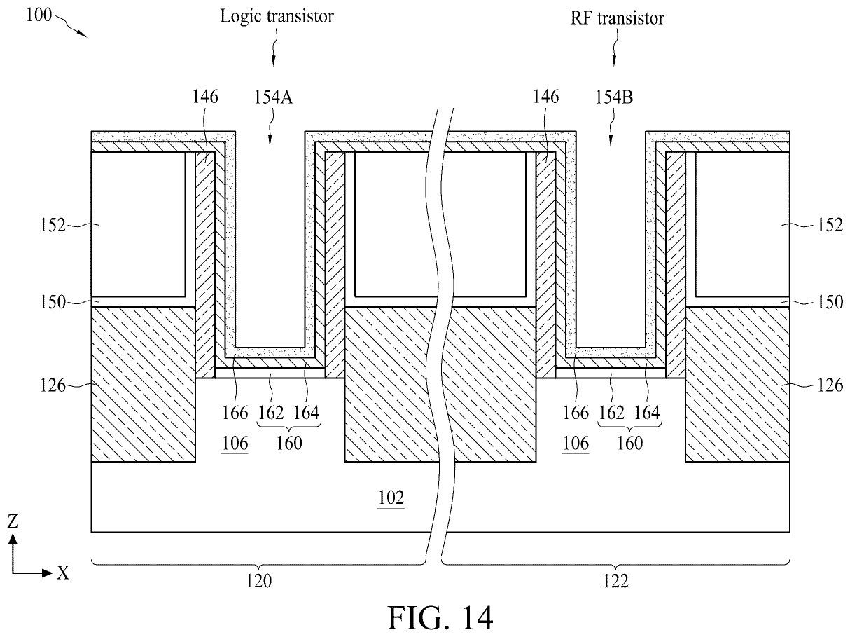

Referring to FIG. 14, a barrier metal layer 166 is formed in both the gate trenches 154A and 154B through deposition. The respective process is illustrated as process 220 in the process flow 200 shown in FIG. 35. The barrier metal layer 166 is deposited on the top surfaces and the sidewalls of the high-k dielectric layer 164. In an embodiment, the barrier metal layer 166 includes a metal nitride, such as TaN, for preventing the metal elements in subsequently formed features from migrating to the gate dielectric layer 160 underneath. The barrier metal layer 166 also functions as an etch stop layer in subsequent etching process. The barrier metal layer 166 is conductive and has a conformal profile. In accordance with some embodiments of the present disclosure, the barrier metal layer 166 is formed using ALD, CVD, or the like.

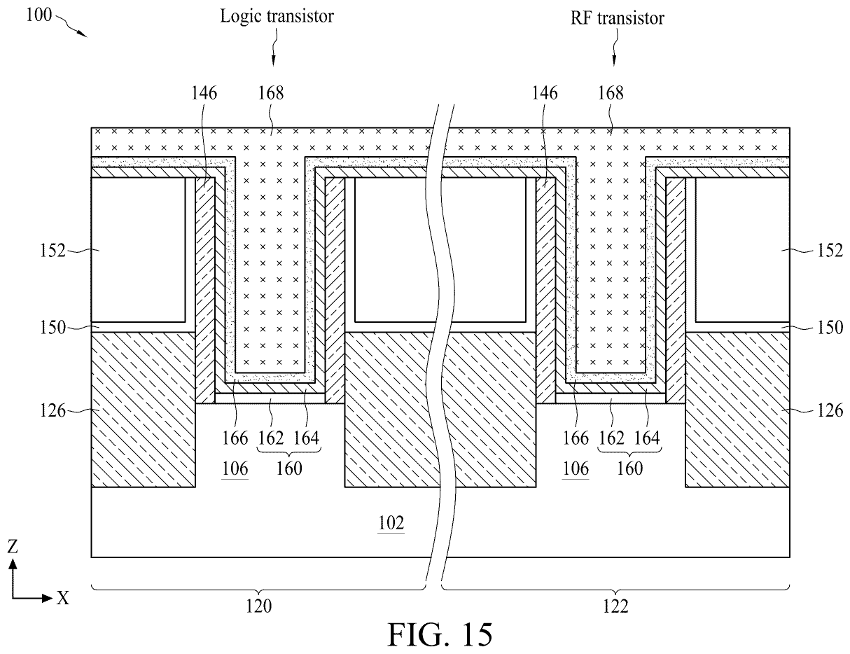

Referring to FIG. 15, a main metal layer 168 is deposited, which fully fills the gate trenches 154A and 154B and covers the top surface of the semiconductor structure 100. The respective process is illustrated as process 222 in the process flow 200 shown in FIG. 35. The main metal layer 168 may be deposited through a deposition method such as ALD, CVD, Plasma Enhanced CVD (PECVD), PVD, plating, or the like. The main metal layer 168 may include a homogenous layer having an entirety formed of a same material. Alternatively, the main metal layer 168 may include a plurality of sub layers formed of materials different from each other. The main metal layer 168 may have an n-type work function or a p-type work function. The main metal layer 168 thus acts as both of the work-function layer and the overlying filling metal. In accordance with some embodiments, the main metal layer 168 is formed of tungsten, aluminum, cobalt, or alloys thereof. In some embodiments, a glue layer (not shown) is conformally deposited over the barrier metal layer 166 prior to the deposition of the main metal layer 168. The glue layer may be a metal containing layer, which may include TiN or other suitable material, and may be formed along sidewalls and bottoms of the gate trenches 154A and 154B using ALD, CVD, PVD, combinations thereof, or the like.

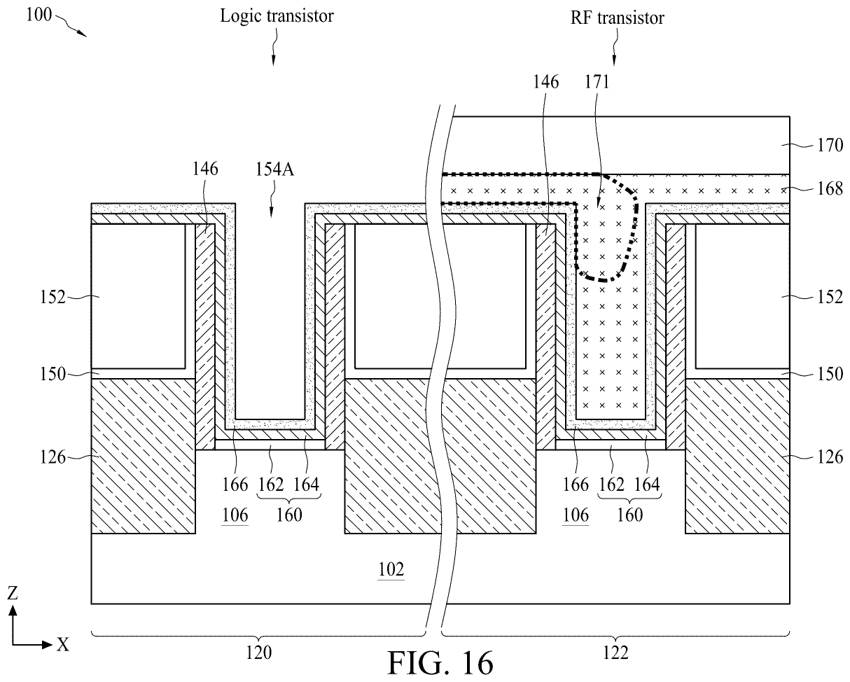

Referring to FIG. 16, a photoresist (resist) layer is deposited over the semiconductor structure 100 and patterned to form a patterned resist layer 170 that exposes the first circuit region 120 for logic circuits. In various embodiments, the photo process used to form the patterned resist layer 170 may also include other steps such as soft baking, mask aligning, exposure, post-exposure baking, developing, rinsing, drying (e.g., spin-drying and/or hard baking), other suitable lithography processes, and/or combinations thereof. After the patterned resist layer 170 is formed, an etching process is performed to remove the main metal layer 168 from the first circuit region 120 for logic circuits. The respective process is illustrated as process 224 in the process flow 200 shown in FIG. 35. The barrier metal layer 166 may function as an etch stop layer during the etching process. In some embodiments, the etching process may include a dry etching process, a wet etching process, and/or a combination thereof. In one example, the barrier metal layer 166 includes TaN, and the etching process is a wet etching process with an etching solution that includes hydrogen peroxide, which auto-dissociates in aqueous solution, to form H+ and HO₂+ ions. In aqueous solution, both HO₂+ and H₂O₂ react with the main metal layer 168 but substantially have no reaction with TaN. The metal etch rate is increased by making the etching solution more acidic such that H+ ions promote dissociation and reaction of H₂O₂ with metal elements in the main metal layer 168. The etching process releases the gate trench 154A and exposes the barrier metal layer 166 in the first circuit region 120 for logic circuits. After the etching process, the patterned resist layer 170 may be removed, for example, by way of a solvent, resist stripper, ashing, or other suitable technique.

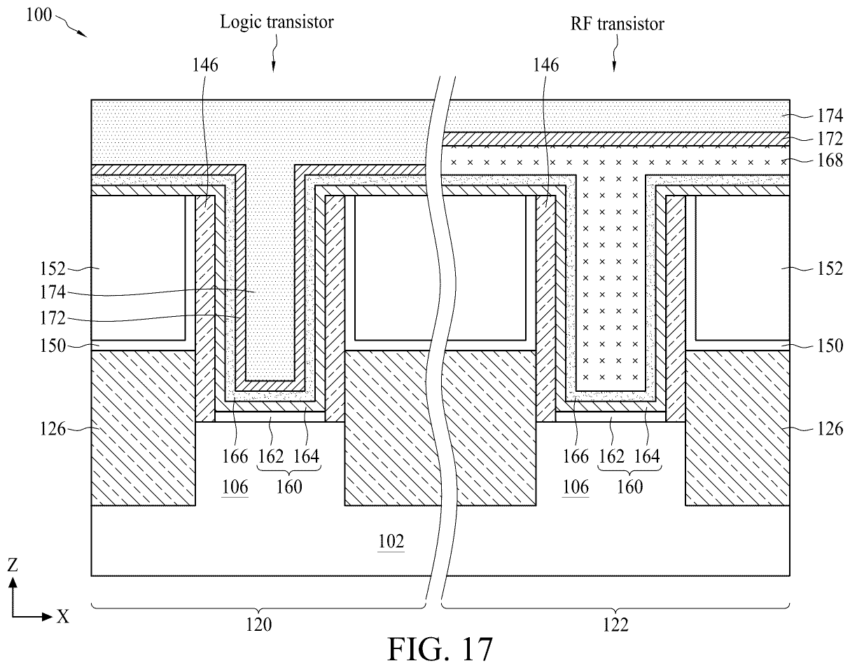

Referring to FIG. 17, a work function layer 172 and a main metal layer 174 over the work function layer 172 are deposited on the top surface of the semiconductor structure 100. The respective process is illustrated as process 226 in the process flow 200 shown in FIG. 35. In embodiments of an n-type transistor, the work function layer 172 may comprise Ti, Ag, Al, TiAl, TiAlN, TiAlC, TaC, TaCN, TaSiN, TaAlC, Mn, Zr, a combination thereof, or the like, and may be formed along sidewalls and bottoms of the gate trench 154A using ALD, CVD, PVD, combinations thereof, or the like. In embodiments of a p-type transistor, the work function layer 172 may comprise TiN, WN, TaN, Ru, Co, a combination thereof, or the like, and may be formed along sidewalls and bottoms of the gate trench 154A using ALD, CVD, PVD, combinations thereof, or the like. The main metal layer 174 may comprise tungsten, aluminum, cobalt, or alloys thereof, and may fill the gate trench 154A through a deposition method such as ALD, CVD, PECVD, PVD, plating, or the like. The work function layer 172 and the main metal layer 174 are also deposited over the main metal layer 168 in the second circuit region 122 for RF circuits.

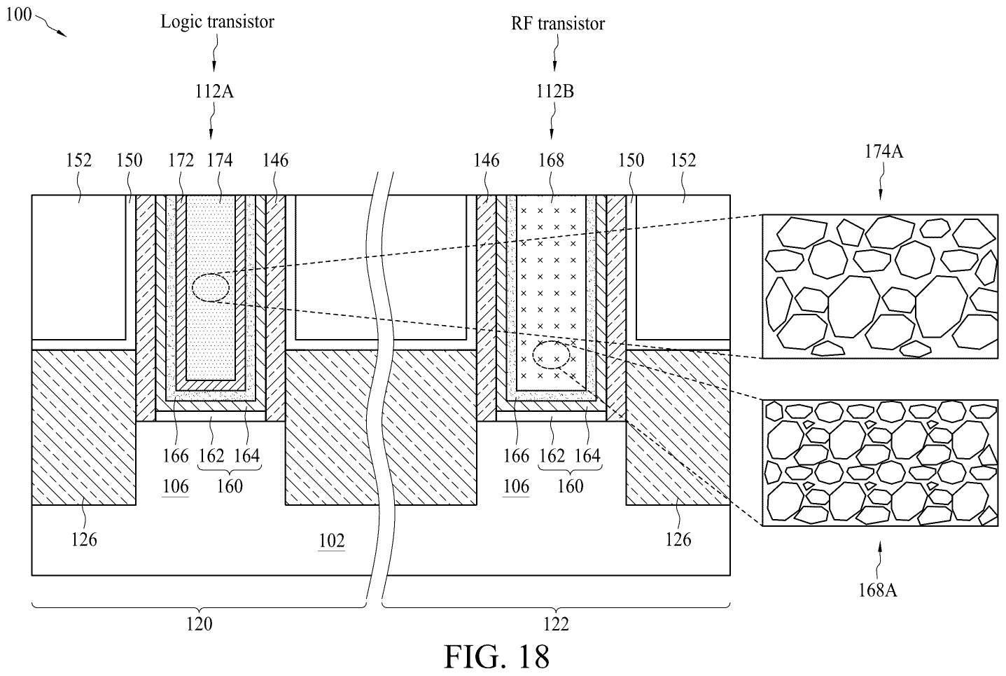

Referring to FIG. 18, after the formation of the work function layer 172 and the main metal layer 174, a planarization process such as a chemical mechanical polish (CMP) process or a mechanical polish process, is performed to remove excess portions of the deposited layers. The respective process is illustrated as process 228 in the process flow 200 shown in FIG. 35. The remaining portions of the layers in the gate trench 154A form the gate stack 112A in the first circuit region 120 for logic circuits, which includes the gate dielectric layer 160, the barrier metal layer 166, the work function layer 172, and the main metal layer (or referred to as metal fill layer) 174. The remaining portions of the layers in the gate trench 154B form the gate stack 112B in the second circuit region 122 for RF circuits, which includes the gate dielectric layer 160, the barrier metal layer 166, and the main metal layer (or referred to as metal fill layer) 168. Each of the gate stacks 112A and 112B may include other sub layers, such as one or more capping layer, glue layer, other suitable layers, and a combination thereof, which are not depicted herein for the sake of simplicity.

In accordance with some embodiments, the main metal layer 168 in the gate stack 112B for RF transistors and the main metal layer 174 in the gate stack 112A for logic transistors are formed of the same material but with different grain sizes. For example, each of the main metal layer 168 and the main metal layer 174 is a homogenous layer having an entirety formed of the same material, such as tungsten (W). A region 168A in the main metal layer 168 has grain sizes smaller than a region 174A in the main metal layer 174. For example, the average grain size of the main metal layer 168 may be smaller than about 5 nm, and the average grain size of the main metal layer 174 may be in the range between about 8 nm and about 500 nm. The ratio of the average grain size of the main metal layer 174 to the average grain size of the main metal layer 168 is greater than 1.2, or may be greater than about 10. The difference in the grain sizes of the main metal layer 168 and the main metal layer 174 may be due to different deposition processes. For example, the metal material in the main metal layer 168 may be deposited in an ALD process, while the metal material in the main metal layer 174 may be deposited in a CVD process.

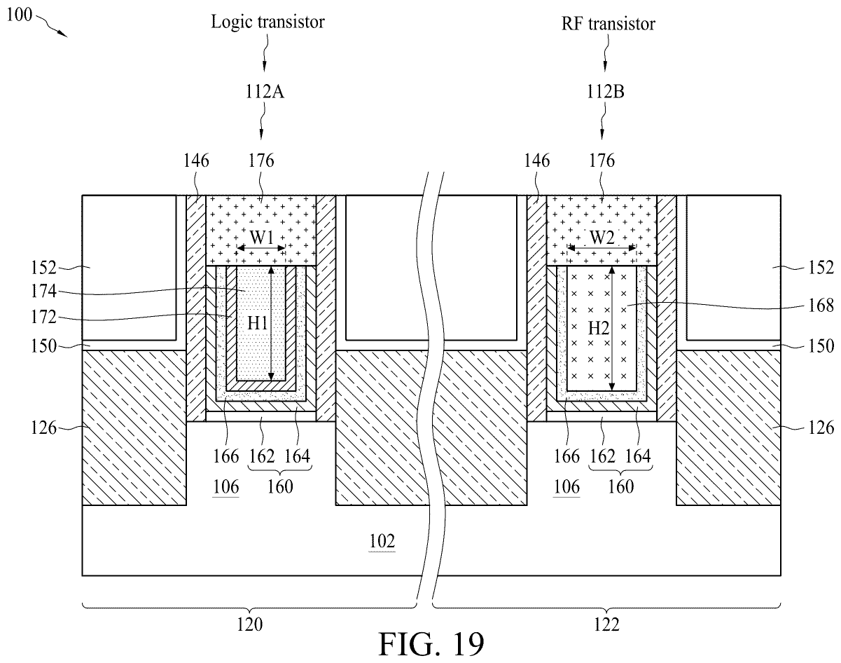

Referring to FIG. 19, an etch-back process is performed to recess the gate stacks 112A and 112B, so that trenches are formed between opposing gate spacers 146. Next, the trenches are filled with a dielectric material to form dielectric region 176. The respective process is illustrated as process 230 in the process flow 200 shown in FIG. 35. The dielectric region 176 is formed of a dielectric material such as silicon nitride, porous silicon oxy-nitride, silicon oxy-carbide, or the like. The dielectric region 176 is also planarized so that its top surface is coplanar with the top surface of the ILD layer 152. Regarding the recessed gate stacks 112A and 112B, due to one extra layer—the work function layer 172—in the gate trench 154A, the main metal layer 174 has a width W1 that is less than a width W2 of the main metal layer 168, a height H1 that is less than a height H2 of the main metal layer 168, and a volume V1 that is less than a volume V2 of the main metal layer 168. In some embodiments, the ratio W2/W1 is greater than 1.2, such as in a range from about 1.2 to about 2; the ratio H2/H1 is greater than about 1.1, such as in a range from about 1.1 to about 1.5; and the volume V2/V1 is greater than 1.4, such as in a range from about 1.4 to about 2.

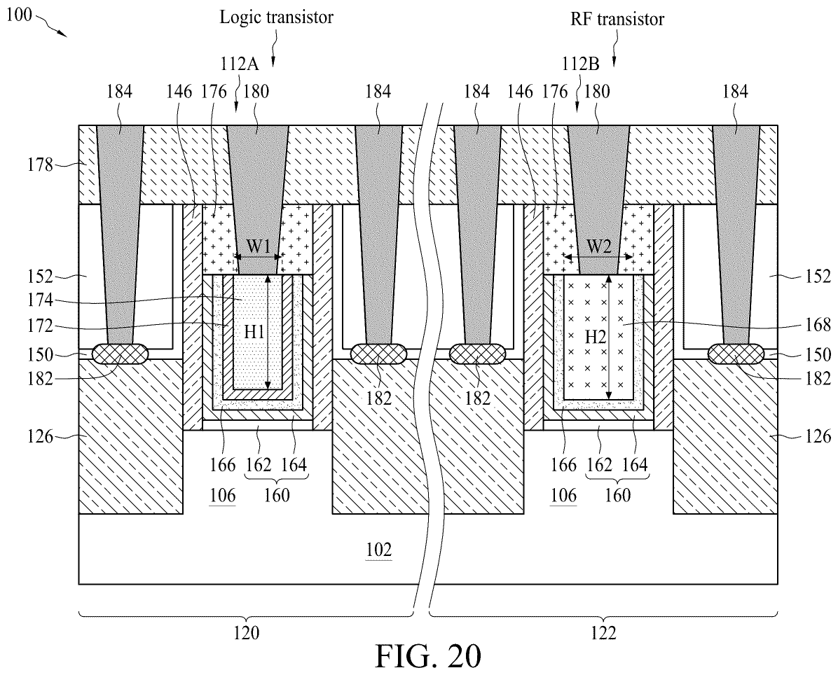

Referring to FIG. 20, a second ILD layer 178, gate contact plugs 180, source/drain silicide regions 182, and source/drain contact plugs 184 are formed. The respective process is illustrated as process 232 in the process flow 200 shown in FIG. 35. The ILD layer 178 may be formed of a dielectric material selected from the same group of candidate materials for forming the ILD layer 152. The formation of source/drain contact plugs 184 includes forming contact openings by etching the ILD layer 178 and the ILD layer 152 to expose the underlying portions of the CESL 150, and then etching the exposed portions of the CESL 150 to reveal the source/drain regions 126. In a subsequent process, the source/drain silicide regions 182 are formed by depositing one or more metals into the contact openings, performing an annealing process to the semiconductor structure 100 to cause reaction between the one or more metals and the semiconductor material of the exposed portions of the source/drain regions 126 to produce the silicide feature, and removing un-reacted portions of the one or more metals, leaving the silicide feature on the bottom of the contact openings. The one or more metals may include titanium (Ti), tantalum (Ta), tungsten (W), nickel (Ni), platinum (Pt), ytterbium (Yb), iridium (Ir), erbium (Er), cobalt (Co), or a combination thereof (e.g., an alloy of two or more metals) and may be deposited using CVD, PVD, ALD, or other suitable methods. The source/drain silicide regions 182 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), a combination thereof, or other suitable compounds. In some embodiments, the source/drain silicide regions 182 have a thickness ranging from about 1 nm to about 15 nm. Subsequently, a filling metallic material such as copper, tungsten, aluminum, cobalt, or the like, is then filled into the contact openings, followed by a planarization to remove excess materials, resulting in the source/drain contact plugs 184. The formation of the gate contact plugs 180 may include etching the second ILD 178 and the dielectric region 176 to expose the gate stacks 112, and filling metallic material such as copper, tungsten, aluminum, cobalt, or the like, in the corresponding openings to form the gate contact plugs 180. The gate contact plugs 180 may also include a diffusion barrier layer, such as titanium nitride. The gate contact plugs 180 and the source/drain contact plugs 184 may be formed sharing some etching and deposition processes (such as forming respective openings and deposition of metallic materials) and the planarization process.

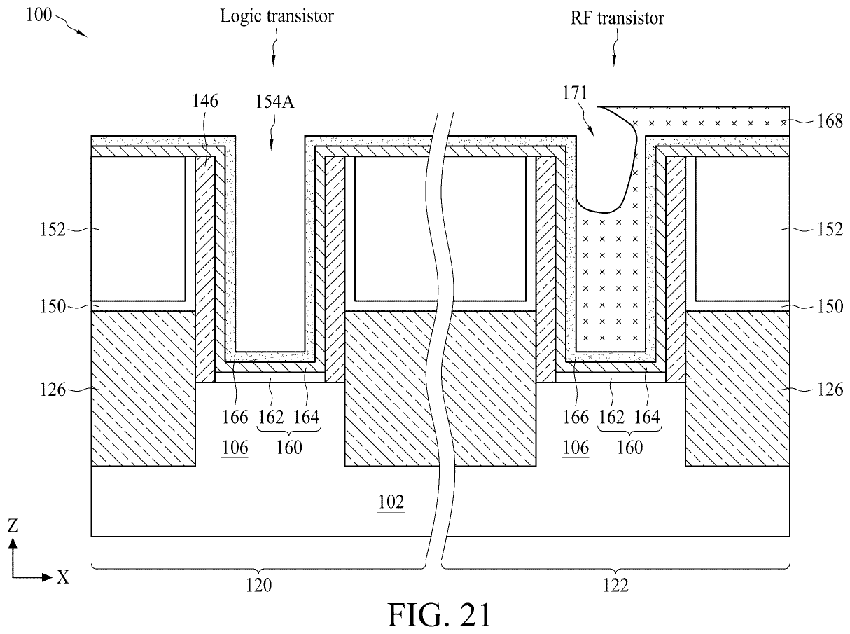

By performing the processes as shown in FIGS. 3-20, an example semiconductor device 100 is formed, which includes logic transistors with gate stacks 112A in the first circuit region 120 for logic circuits and RF transistors with gate stacks 112B in the second circuit region 122 for RF circuits. As illustrated, the gate stacks 112A and the gate stacks 112B may be formed sharing some common formation processes, such as the formation of dummy gate stacks, the formation of source/drain regions, and replacing the dummy gate stacks with compositions in forming the gate stacks 112B in both the circuit regions 120 and 122. A separate etching process and deposition process is performed in the first circuit region 120 to replace the main metal layer 166 with other metal layers (e.g., the work function layer 172 and the main metal layer 174), which are more suitable for forming the gate stacks 112A for logic circuit applications. Referring back to FIG. 16, during the etching process, even though the main metal layer 168 in the second circuit region 122 is covered by the patterned resist layer 170, a portion under the edges of the patterned resist layer 170 would eventually be exposed to the etching solution applied at process 224 in the process flow 200 shown in FIG. 35. The etching solution may first erode this portion of the main metal layer 168 in forming a gap between the edges of the patterned resist layer 170 and the underneath barrier metal layer 166, and gradually expand the gap into the gate trenches in the second circuit region 122. A boundary of such a gap 171 after the etching process is illustrated as dashed lines in FIG. 16. A possible resultant structure after the etching process and the removal of the patterned resist layer 170 is further illustrated in FIG. 21. As shown in FIG. 21, the gate stack 112B of the RF transistors is damaged due to the lateral leakage of the etching solution into the RF regions, and the RF performance of the device may have been compromised.

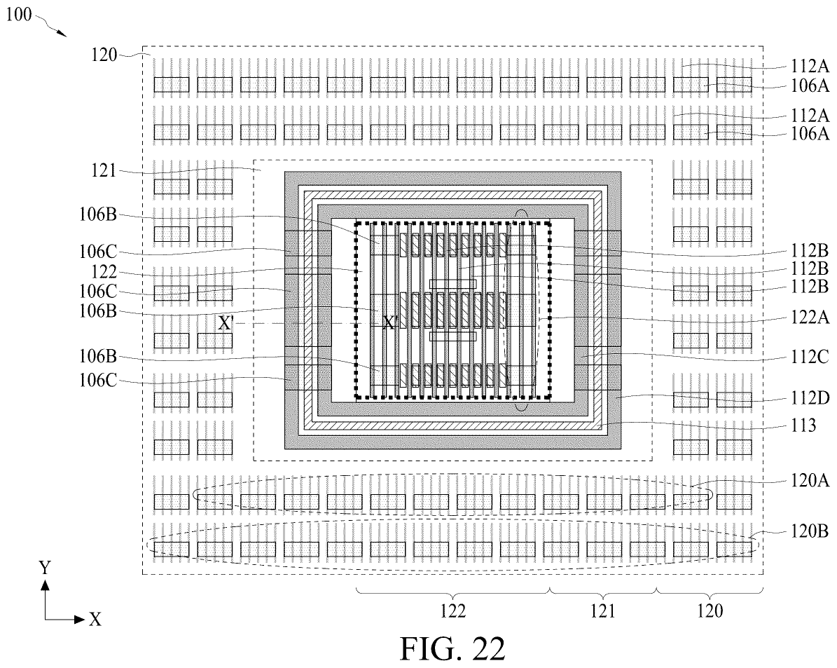

FIG. 22 is a layout of the semiconductor structure 100 constructed, in portion, in accordance with some embodiments. The semiconductor structure 100 has a layout optimized for enhanced circuit performance to both logic circuits in the first circuit region 120 and RF circuits in the second circuit region 122. A center region of the layout is an exemplary second circuit region 122. A peripheral region of the layout is an exemplary first circuit region 120. In the illustrated embodiment, the first circuit region 120 surrounds the second circuit region 122. Between the first circuit region 120 and the second circuit region 122 is a guard ring region 121. The guard ring region 121 includes one or more guard rings surrounding the second circuit region 122.

The first circuit region 120 includes protruding fins 106A and gate stacks 112A, which are used for forming logic transistors. In furtherance of the embodiment, some rows and/or columns of the transistors that are closest to the second circuit region 122, such as an illustrated row denoted in a region 120A, may be dummy transistors. Dummy transistors are not functional transistors but configured around a functional block. The dummy transistors are disposed for other purpose, such as tuning the pattern density and/or isolation. The dummy transistors (including dummy gates in the dummy transistors) may have a similar structure as a functional transistor. For example, the dummy gates in the dummy transistors may include the gate stacks 112A as in the functional transistors. Other than the dummy transistors, the rest transistors formed in rows and columns of outer circles in the first circuit region 120, such as in an illustrated row denoted in a region 120B, may be functional transistors.

The second circuit region 122 includes protruding fins 106B and gate stacks 112B, which are used for forming RF transistors. In furtherance of the embodiment, some rows and/or columns of the transistors that are at the edges of the second circuit region 122, such as an illustrated column denoted in a region 122A, may be dummy RF transistors. Dummy RF transistors are not functional RF transistors but configured around a functional block. The dummy RF transistors are disposed for other purpose, such as tuning the pattern density and/or isolation. The dummy RF transistors (including dummy gates in the dummy RF transistors) may have a similar structure as a functional RF transistor. For example, the dummy gates in the dummy RF transistors may include the gate stacks 112B as in the functional RF transistors. Other than the dummy RF transistors, the rest transistors formed in the second circuit region 122 may be functional RF transistors.

The guard ring region 121 includes one or more guard rings. Guard rings are disposed and configured to shield interference, reduce noise, and enhance circuit performance. For example, guard rings may be configured to bias the substrate in order to shield interference. In the depicted embodiments, the guard ring region 121 includes protruding fins 106C and gate stacks 112C and 112D disposed on the fins 106C. The fins 106C may have widths (measured in the Y-direction) different from the fins 106A and 106B. For example, each of the fins 106C may have a larger width than the fins 106A and 106B. Further, the widths of the fins 106C may be non-uniform. In the depicted embodiment, some of the fins 106C have a larger width than others.

Each of the gate stacks 112C and 112D extends continuously to fully surround (or encircle) the second circuit region 122, forming moat-like structures. In the illustrated embodiment, each of the gate stacks 112C and 112D is oriented to be in parallel with the adjacent edges of the second circuit region 122. The moat-like structure including the gate stack 112C is configured as a first guard ring (or inner guard ring). The moat-like structure including the gate stack 112D is configured as a second guard ring (or outer guard ring). The gate stacks 112C and 112D may be bias to a power supply voltage (e.g., electrically grounded) through gate contact plugs or left floating. Further, the gate stacks 112C and 112D are disposed on the same set of the fins 106C and sandwiching dummy source/drain regions (e.g., epitaxial features) therebetween. The dummy source/drain regions sandwiched between the gate stacks 112C and 112D are electrically grounded through a metal line 113 that is connected with respective source/drain contact plugs. In the illustrated embodiment, the metal line 113 is positioned between the gate stacks 112C and 112D and extends continuously to fully surround (or encircle) the second circuit region 122.

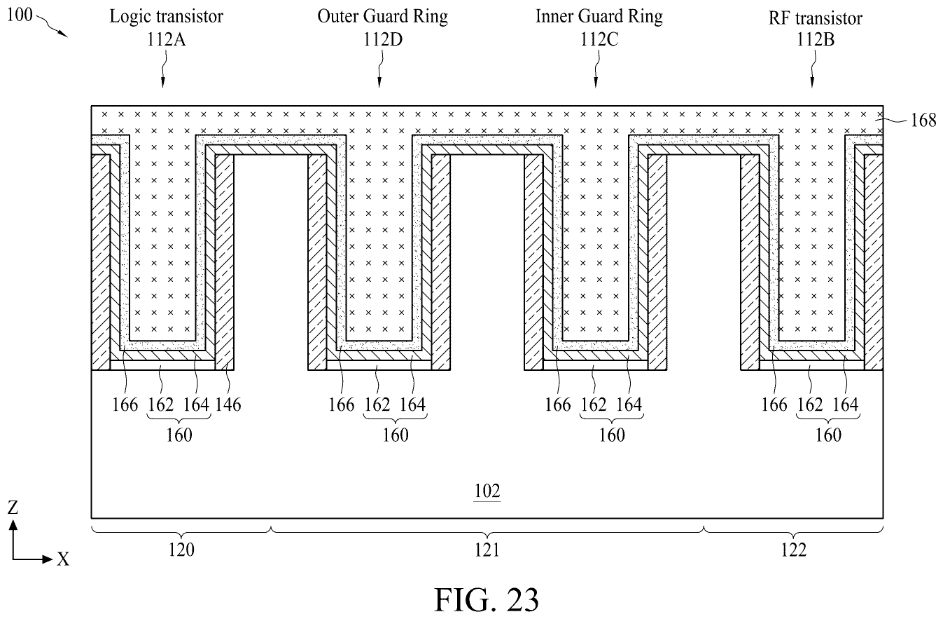

By fully surrounding the second circuit region 122, the moat-like guard rings block the etching solution from leaking into the gate stacks in the second circuit region 122 at least at process 224 in the process flow 200 shown in FIG. 35, which is further illustrated in FIGS. 23-31, besides other benefits such as providing noise interference shielding to high frequency operation of the surrounded RF circuits. FIGS. 23-31 are cross-sectional views along the line X′-X′ in FIG. 22. FIGS. 23-31 have been simplified for the sake of clarity to better understand the inventive concepts of the present disclosure. For example, source/drain regions, silicide features, CESL, ILD layers, and some other features are omitted, while additional features can be added in the semiconductor structure 100, and some of the features described below can be replaced, modified, or eliminated in other embodiments of the semiconductor structure 100. In some embodiments, the semiconductor structure 100 is substantially similar to the one depicted above with reference to FIGS. 3-20 but with an outer guard ring and an inner guard ring inserted between the logic transistors in the first region 120 and the RF transistors in the second region 122.

Referring to FIG. 23, at the conclusion of process 222 in the process flow 200 shown in FIG. 35, the gate dielectric layer 160 (including IL 162, high-k dielectric layer 164), the barrier metal layer 166 (e.g., TaN), and the main metal layer 168 (e.g., tungsten) are sequentially deposited in the gate trenches of the first circuit region 120, the guard ring region 121, and the second circuit region 122. State differently, the gate stacks 112A-D across the first circuit region 120, the guard ring region 121, and the second circuit region 122 initially have the same material composition as what is later to be in the gate stack 112B of the RF transistors.

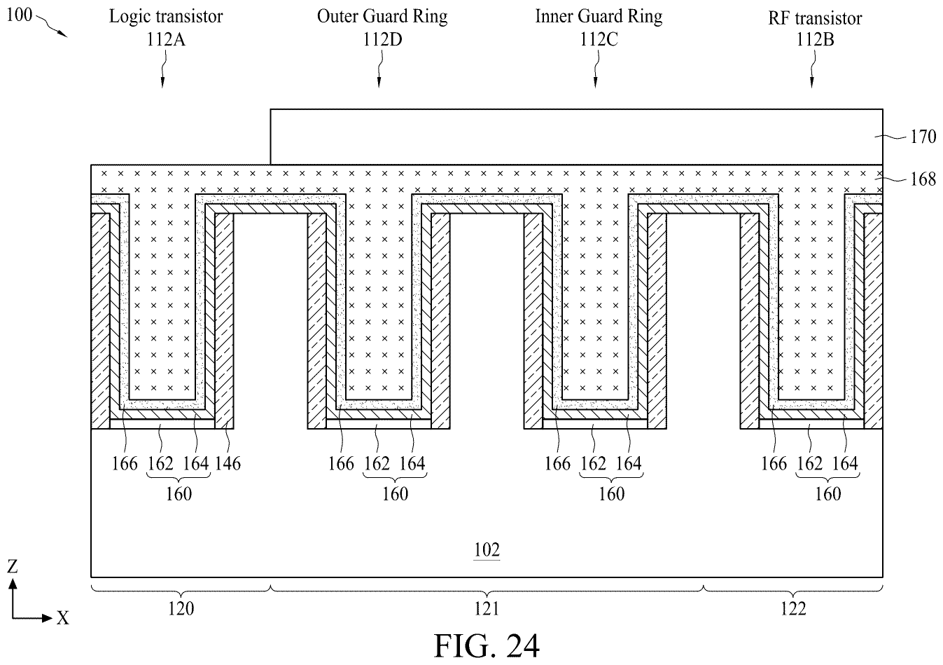

Referring to FIG. 24, the patterned resist layer 170 that exposes the first circuit region 120 for logic circuits is formed. The guard ring region 121 and the second circuit region 122 are covered by the patterned resist layer 170. In various embodiments, the photo process used to form the patterned resist layer 170 may also include other steps such as soft baking, mask aligning, exposure, post-exposure baking, developing, rinsing, drying (e.g., spin-drying and/or hard baking), other suitable lithography processes, and/or combinations thereof.

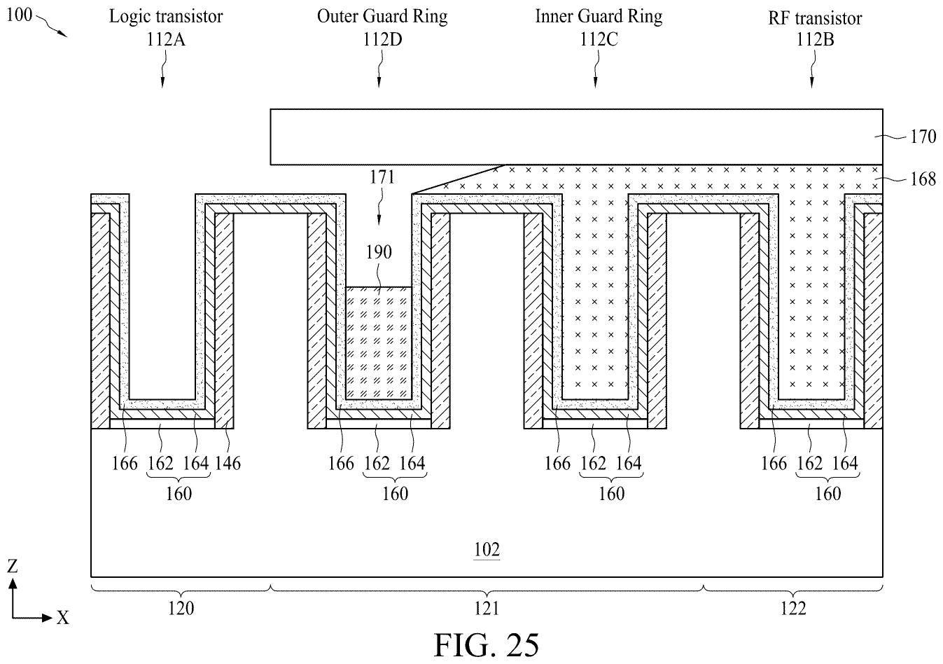

Referring to FIG. 25, an etching process is performed to remove the main metal layer 168 from the first circuit region 120 for logic circuits. The barrier metal layer 166 may function as an etch stop layer during the etching process. In one example, the barrier metal layer 166 includes TaN, and the etching process is a wet etching process with an etching solution that includes hydrogen peroxide, which auto-dissociates in aqueous solution, to form H+ and HO₂+ ions. In aqueous solution, both HO₂+ and H₂O₂ react with the main metal layer 168 but substantially have no reaction with TaN. The etching process releases the gate trench in the first circuit region 120 and exposes the barrier metal layer 166 in the first circuit region 120 for logic circuits. However, lateral etching of the etching solution may occur, such that a portion of the main metal layer 168 under the edges of the patterned resist layer 170 may be exposed to the etching solution and eroded away. A gap 171 appears under the patterned resist layer 170 and extends laterally towards the gate stack 112B in the second circuit region 122. The gate stacks 112D and 112C of the outer and inner guard rings function as a barrier that slows down the lateral etching progress. Even though the lateral leakage of the etching solution into regions under the patterned resist layer 170 may etches away the main metal layer 168 in the outer guard ring and/or inner guard ring as well, when the gate trench in the first circuit region 120 is released and the etching process stops (e.g., by controlling in a timer mode), the gate stack 112B in the second circuit region 122 remains intact. In the illustrated embodiment as shown in FIG. 25, the main metal layer 168 in the gate stack 112D of the outer guard ring is etched, and the gap 171 extends even to a region between the outer guard ring and the inner guard ring. Yet, the gate stack 112C in the inner guard ring and the gate stack 112B in the second circuit region 122 remain intact. Some of the etching solution due to the lateral leakage and/or etching residue (denoted as 190 in FIG. 25) may accumulate in the released gate trench of the outer guard ring, since it is hard for the molecules to escape through the narrow opening of the gap 171. Etching solution and/or etching residue 190 eventually evaporates into the ambient environment or is cleaned by a cleaning process after the patterned resist layer 170 is subsequently removed. Even though the gate stack 112D of the outer guard ring is damaged due to the lateral leakage of the etching solution, the gate stack 112D is not a functional gate stack and the RF performance of the device is not compromised.

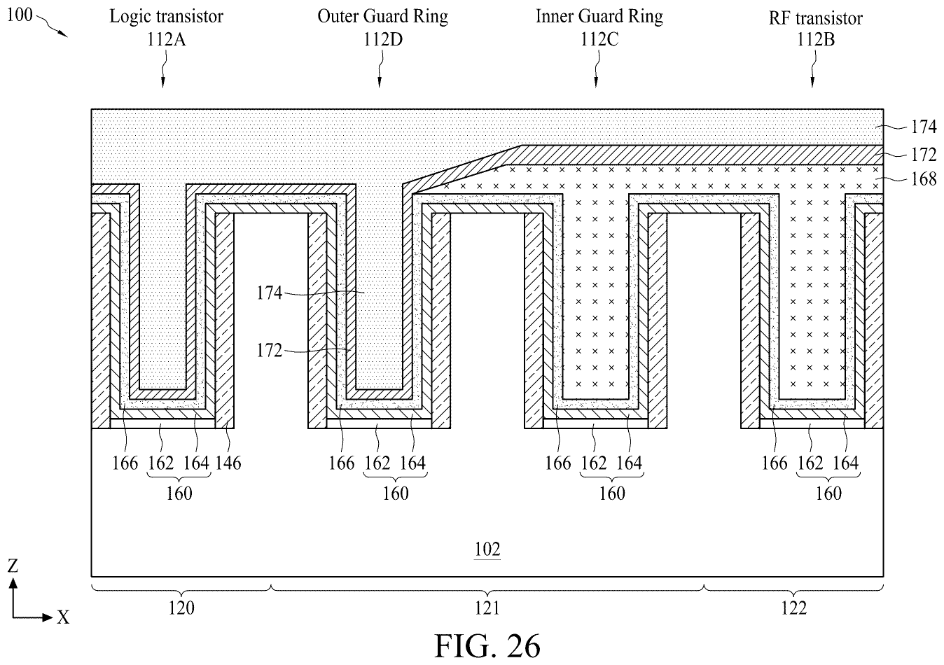

Referring to FIG. 26, a work function layer 172 and a main metal layer 174 over the work function layer 172 are deposited in the gate trenches in the first circuit region 120 and the outer guard ring and over the main metal layer 168 remaining in the inner guard ring and the second circuit region 122. The work function layer 172 adjusts the work function of the logic transistors. The main metal layer 174 may have the same material composition as the main metal layer 168, such as tungsten, but differ in grain sizes as discussed above with reference to FIG. 18.

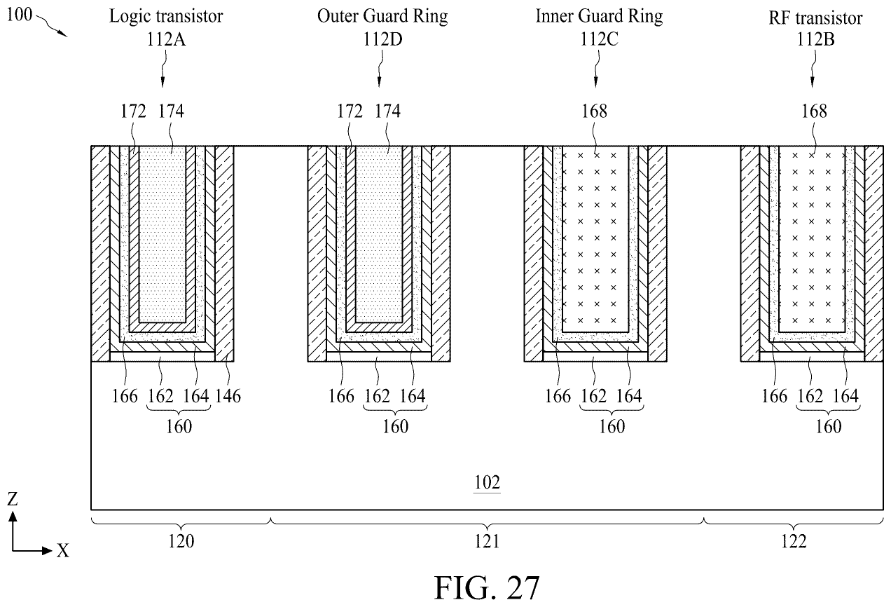

Referring to FIG. 27, after the formation of the work function layer 172 and the main metal layer 174, a planarization process such as a chemical mechanical polish (CMP) process or a mechanical polish process, is performed to remove excess portions of the deposited layers. The remaining portions of the layers in the gate trenches form the gate stack 112A in the logic transistors, the gate stack 112D in the outer guard ring, the gate stack 112C in the inner guard ring, and the gate stack 112B in the RF transistors. The gate stacks 112A and 112D each include the gate dielectric layer 160, the barrier metal layer 166, the work function layer 172, and the main metal layer (or referred to as metal fill layer) 174. The gate stacks 112C and 112B each include the gate dielectric layer 160, the barrier metal layer 166, and the main metal layer (or referred to as metal fill layer) 168. Each of the gate stacks 112A-D may include other sub layers, such as one or more capping layer, glue layer, other suitable layers, and a combination thereof, which are not depicted herein for the sake of simplicity.

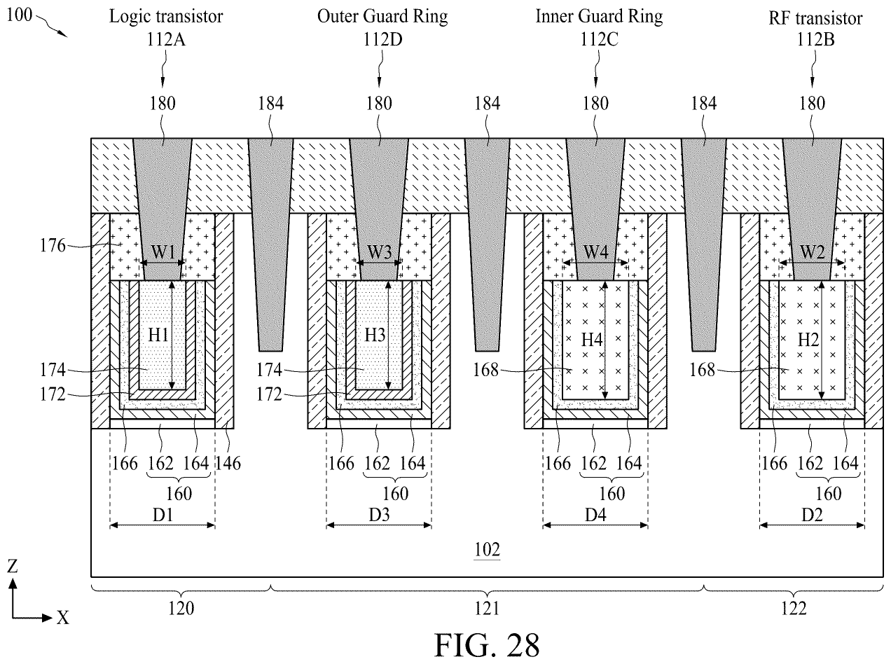

Referring to FIG. 28, an etched-back process is performed to recess the gate stacks 112A-D, a dielectric region 176 is formed on the recessed gate stacks 112A-D, and gate contact plugs 180 and source/drain contact plugs 184 are subsequently formed. In some embodiments, the gate contact plugs 180 on the outer and inner guard rings electrically ground the gate stacks 112D and 112C, respectively. Alternatively, the gate stacks 112D and 112C of the outer and inner guard rings may be left floating. In some embodiments, the source/drain contact plug 184 landing on the dummy source/drain region (epitaxial feature) sandwiched between the gate stacks 112D and 112C electrically couples the dummy source/drain region to the metal line 113 (FIG. 22) thereabove, which provides electrical grounding. Regarding the recessed gate stacks 112D and 112C, a gate width D3 of the gate stack 112D may equal a gate width D4 of the gate stack 112C in some embodiments. Yet, due to one extra layer—the work function layer 172—in the gate stack 112D, the main metal layer 174 has a width W3 that is less than a width W4 of the main metal layer 168, a height H3 that is less than a height H4 of the main metal layer 168, and a volume V3 that is less than a volume V4 of the main metal layer 168. In some embodiments, the ratio W4/W3 is greater than 1.2, such as in a range from about 1.2 to about 2; the ratio H4/H3 is greater than about 1.1, such as in a range from about 1.1 to about 1.5; and the volume V4/V3 is greater than 1.4, such as in a range from about 1.4 to about 2. In some embodiments, gate widths of the guard rings are wider than those of the RF transistors and logic transistors, and there are D4=D3>D2>D1, W4>W3>W2>W1, H4=H2 >H3=H1, and V4>V3>V2>V1 for the main metal layers 168 and 174 in different regions.

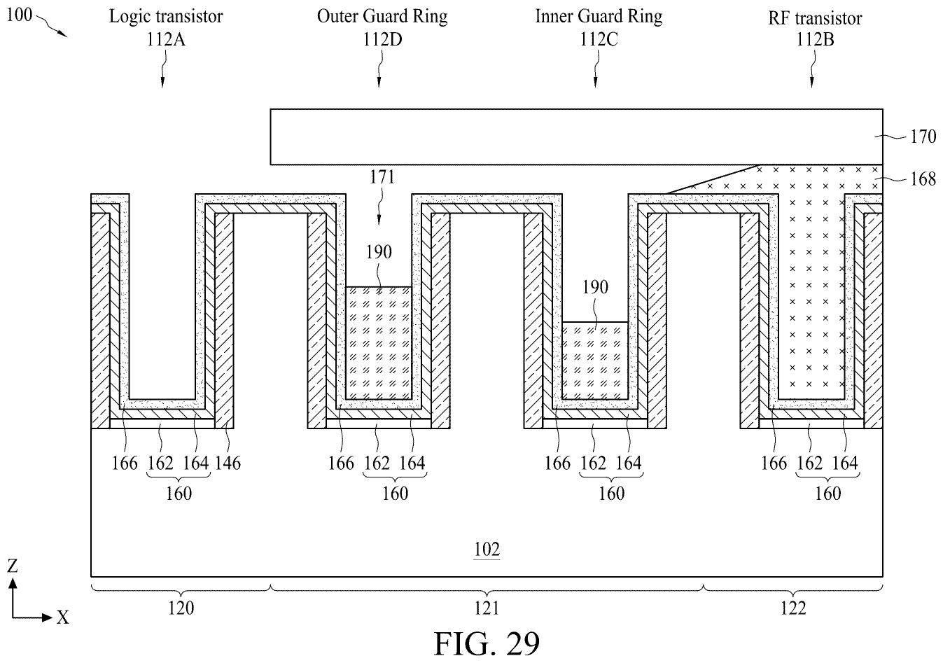

FIG. 29 illustrates an alternatively embodiment when the lateral leakage of the etching solution further removes the main metal layer 168 from the gate trench in the inner guard ring, such as due to an over etching with a longer etching time to ensure the main metal layer 168 is fully removed form the gate trenches in the first circuit region 120. Even though the gate stack 112D of the outer guard ring and the gate stack 112C of the inner guard ring are both damaged due to the lateral leakage of the etching solution, the gate stack 112B in the RF transistors remains intact. The gate stacks 112D and 112C are not functional gate stacks and the RF performance of the device is not compromised.

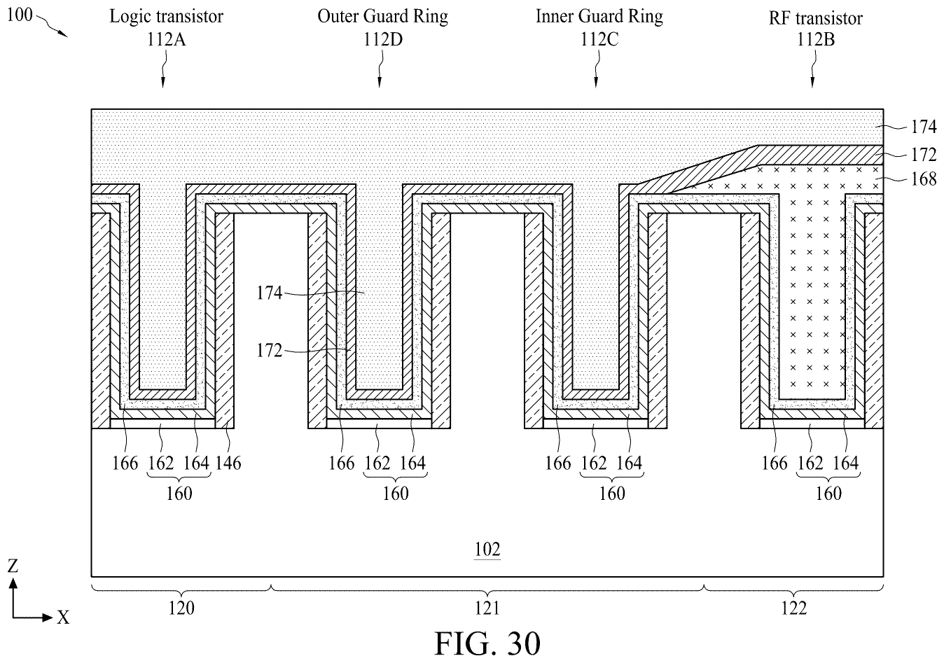

Referring to FIG. 30, a work function layer 172 and a main metal layer 174 over the work function layer 172 are deposited in the gate trenches in the first circuit region 120, the outer guard ring and the inner guard ring, and over the main metal layer 168 remaining in the second circuit region 122. The work function layer 172 adjusts the work function of the logic transistors. The main metal layer 174 may have the same material composition as the main metal layer 168, such as tungsten, but differ in grain sizes as discussed above with reference to FIG. 18.

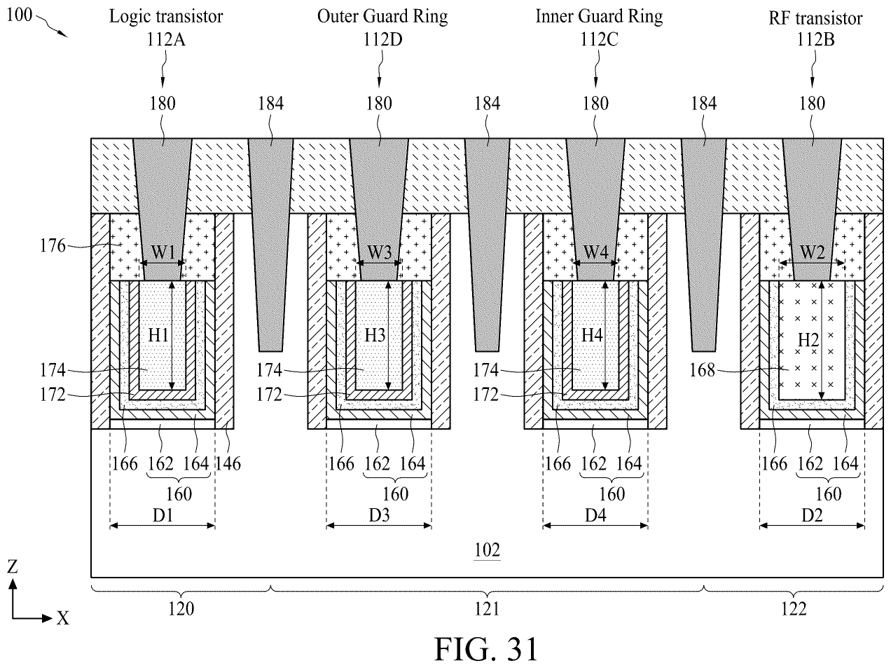

Referring to FIG. 31, after a planarization process to remove excess portions of the deposited layers, an etched-back process is performed to recess the gate stacks 112A-D, a dielectric region 176 is formed on the recessed gate stacks 112A-D, and gate contact plugs 180 and source/drain contact plugs 184 are subsequently formed. The gate stack 112D in the outer guard ring and the gate stack 112C in the inner guard ring include the same material layers. In some embodiments, a gate width D3 of the gate stack 112D may equal a gate width D4 of the gate stack 112C in some embodiments, and the main metal layer 174 has the same dimensions (e.g., widths W3=W4, heights H3=H4, and volumes V3=V4) in both the gate stacks 112D and 112C. In some embodiments, gate widths of the guard rings are wider than those of the RF transistors and logic transistors, and there are D4=D3>D2>D1, W4=W3>W2>W1, H2 >H4=H3=H1, and V4=V3>V2>V1 for the main metal layers 168 and 174 in different regions.

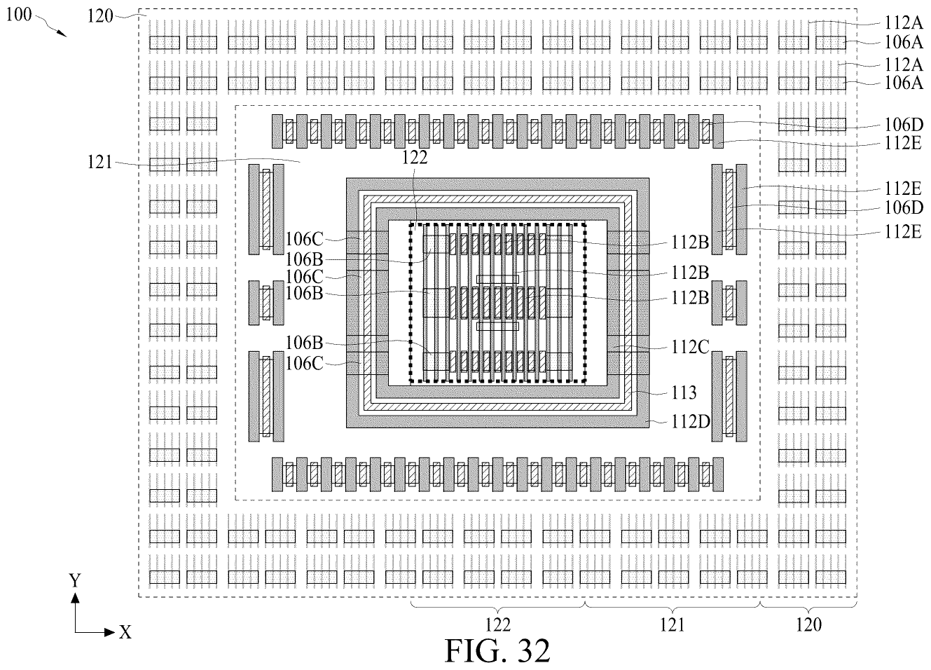

FIG. 32 is an alternative embodiment of a layout of the semiconductor structure 100 constructed, in portion. The illustrated top view is substantially similar to the one depicted in FIG. 22, but with an extra guard ring in the guard ring region 121, which comprises the gate stacks 112E formed on the protruding fins 106D. The extra guard ring is deposited between the outer guard ring and the first circuit region 120. Unlike the outer and inner guard rings discussed above, the extra guard ring is not continuous but segmented, which is also referred to as segmented guard ring, as a comparison to the moat-like guard rings. Particularly, the gate stacks 112E do not continuously extend in encircling the second circuit region 122, but are segmented and extending lengthwise in the Y-direction. The segmented guard ring biases the substrate to ground, providing extra shielding of the noise interference under high frequency operations. But the gaps between the segments of the segmented guard ring would not effectively block the lateral leakage of the etching solution from occurring. Thus, the material compositions of the gate stacks 112E of the segmented guard ring is substantially similar to those of the gate stack 112A in the first circuit region and possibly the gate stack 112D in the outer guard ring, but different from those of the gate stack 112B protected in the second circuit region 122.

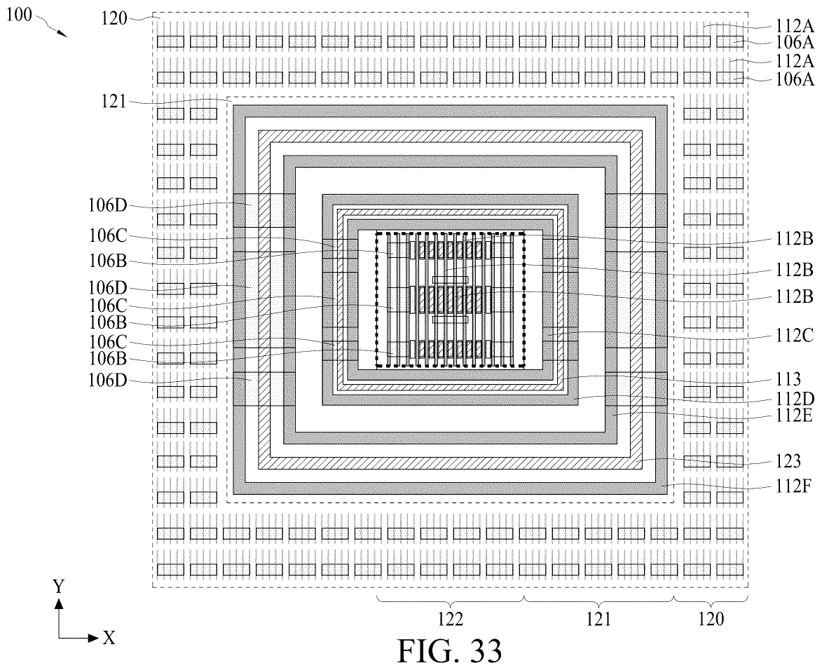

FIG. 33 is another alternative embodiment of a layout of the semiconductor structure 100 constructed, in portion. The illustrated top view is substantially similar to the one depicted in FIG. 22, but with an extra moat-like guard ring in the guard ring region 121, which comprises the protruding fins 106D and gate stacks 112E and 112F disposed on the fins 106D. The fins 106D may have different widths (measured in the Y-direction) from the fins 106A and 106B. For example, some of the fins 106D may have a larger width than any of the fins 106A, 106B, and 106C. Further, the widths of the fins 106D may be non-uniform with some of the fins 106D having a larger width than others.

Each of the gate stacks 112E and 112F extends continuously to fully surround (or encircle) the second circuit region 122. In the illustrated embodiment, each of the gate stacks 112E and 112F is oriented to be in parallel with the adjacent edges of the second circuit region 122. The moat-like structure including the gate stack 112E is configured as a third guard ring (or second inner guard ring). The moat-like structure including the gate stack 112F is configured as a fourth guard ring (or second outer guard ring). The gate stacks 112E and 112F may be bias to a power supply voltage (e.g., electrically grounded) through gate contact plugs or left floating. Further, the gate stacks 112E and 112F are disposed on the same set of the fins 106D and sandwiching dummy source/drain regions (e.g., epitaxial features) therebetween. The dummy source/drain regions sandwiched between the gate stacks 112E and 112F are electrically grounded through a metal line 123 that is connected with the source/drain contact plugs. In the illustrated embodiment, the metal line 123 is positioned between the gate stacks 112E and 112F and extends continuously to fully surround (or encircle) the second circuit region 122. In some embodiments, the gate widths of the gate stacks 112C and 112D may equal each other, and the gate widths of the gate stacks 112E and 112F may equal each other but larger than the ones of the gate stacks 112C and 112D. A ratio of the gate width of the gate stacks 112E and 112F over the gate width of the gate stacks 112C and 112D may be greater than about 1.5 in some examples. Further, a gate spacing between the gate stacks 112E and 112F may be larger than a gate spacing between the gate stacks 112C and 112D, such as a ratio greater than about 1.5 in some examples. The line width of the metal line 123 is larger than that of the metal line 113, in some embodiments.

By having two pairs of moat-like guard rings—a first pair of guard rings comprising dummy gate stacks 112C and 112D and a second pair of guard rings comprising dummy gate stacks 112E and 112F—the second circuit region 122 is better protected from gate damages caused by lateral leakage of the etching solution. In one example, the lateral leakage reaches the second outer guard ring, and the gate stack 112F of the second outer guard ring has the same metal gate composition as the logic transistors in the first circuit region 120, while the gate stacks 112E, 112D, 112C have the same metal gate composition as the RF transistors in the second circuit region 122. In one example, the lateral leakage reaches the second inner guard ring, and the gate stack 112F of the second outer guard ring and the gate stack 112E of the second inner guard ring have the same metal gate composition as the logic transistors in the first circuit region 120, while the gate stacks 112D, 112C have the same metal gate composition as the RF transistors in the second circuit region 122. In one example, the lateral leakage reaches the first outer guard ring, and the gate stack 112F of the second outer guard ring, the gate stack 112E of the second inner guard ring, and the gate stack 112D of the first outer guard ring have the same metal gate composition as the logic transistors in the first circuit region 120, while the gate stack 112C has the same metal gate composition as the RF transistors in the second circuit region 122. In one example, the lateral leakage reaches the first inner guard ring, and the gate stack 112F of the second outer guard ring, the gate stack 112E of the second inner guard ring, the gate stack 112D of the first outer guard ring, and the gate stack 112C of the first inner guard ring have the same metal gate composition as the logic transistors in the first circuit region 120, while the RF transistors in the second circuit region 122 are protected from the lateral leakage and have the different metal gate composition for RF applications.

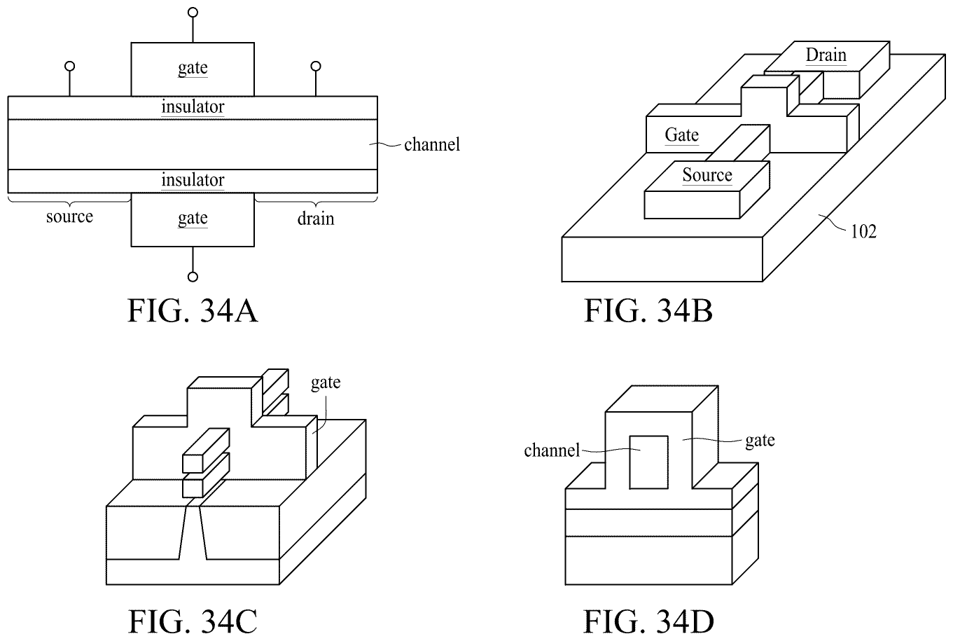

FIG. 34A-D illustrate some example transistors in which the embodiments of the present disclosure may be applied, so that these transistors may be used as logic transistors and/or RF transistors. FIG. 34A illustrates a cross-sectional view of a double-gate transistor, wherein two gates are formed on opposing side of the channel. FIG. 34B illustrates a perspective view of a FinFET formed on isolation region 102. FIG. 34C illustrates the perspective view of a GAA transistor including two channel layers with a metal gate stack wrapping around each of the two channel layers. FIG. 34D illustrates a GAA transistor include one channel layer. The gate stacks of these transistors may be formed adopting the embodiments of the present disclosure to improve the circuit performance.

The present disclosure provides various embodiments of an IC structure having multiple circuit regions with different functions, such as logic circuit and RF circuit. In various embodiments described above, RF circuit is fully surrounded by one or more moat-like guard rings, thereby eliminating or reducing the process defects due to lateral leakage of etching solutions during replacement gate processes. Accordingly, the overall IC structure has enhanced circuit performance without degradation of the fabrication quality.

In one example aspect, the present disclosure provides a semiconductor structure. The semiconductor structure includes a semiconductor substrate having a first circuit region and a second circuit region, first transistors that include first gate stacks disposed in the first circuit region, second transistors that include second gate stacks disposed in the second circuit region, the first gate stacks and the second gate stacks having different material compositions, and a guard ring structure disposed between the first circuit region and the second circuit region, the guard ring structure fully surrounding the second circuit region. In some embodiments, the second transistors are high-frequency transistors and the first transistors are logic transistors. In some embodiments, the first circuit region fully surrounds the second circuit region. In some embodiments, the guard ring structure includes at least a dummy gate stack extends continuously and fully surrounds the second circuit region. In some embodiments, the guard ring structure includes a first dummy gate stack and a second dummy gate stack, wherein each of the first and second dummy gate stacks extends continuously and fully surrounds the second circuit region. In some embodiments, the first and second dummy gate stacks are disposed on at least a same active region. In some embodiments, the active region has a fin shape protruding from the semiconductor substrate. In some embodiments, the first gate stacks and the first dummy gate stack include a same material composition that is different from the second gate stacks and the second dummy gate stack. In some embodiments, the first gate stacks, the first dummy gate stack, and the second dummy gate stack include a same material composition that is different from the second gate stacks. In some embodiments, the first gate stacks have a first gate pitch less than a reference pitch, and the second gate stacks have a second gate pitch larger than the reference pitch.

In another example aspect, the present disclosure provides a semiconductor structure. The semiconductor structure includes a semiconductor substrate having a logic circuit region and a radio frequency (RF) circuit region, first transistors that include first gate stacks disposed in the logic circuit region, second transistors that include second gate stacks disposed in the RF circuit region, and a guard ring structure disposed between the logic circuit region and the RF circuit region, the guard ring structure including an inner guard ring fully surrounding the RF circuit region and an outer guard ring fully surrounding the inner guard ring and the RF circuit region. In some embodiments, the guard ring structure further includes an epitaxial feature disposed between the inner guard ring and the outer guard ring, and a metal line electrically coupled to the epitaxial feature, and the metal line fully surrounds the RF circuit region. In some embodiments, the outer guard ring includes a first dummy gate stack, and the inner guard ring includes a second dummy gate stack, and wherein the first and second dummy gate stacks are disposed on a same active region. In some embodiments, the outer guard ring includes a first dummy gate stack, and the inner guard ring includes a second dummy gate stack, and the first dummy gate stack includes a first material composition same as the first gate stacks, and the second dummy gate stack includes a second material composition same as the second gate stacks. In some embodiments, the outer guard ring includes a first dummy gate stack, and the inner guard ring includes a second dummy gate stack, and the first and second dummy gate stacks include a material composition same as the first gate stacks but different from the second gate stacks. In some embodiments, the inner guard ring includes a first metal fill layer, the outer guard ring includes a second metal fill layer, and the first metal fill layer has a width larger than the second metal fill layer. In some embodiments, the guard ring structure is a first guard ring structure, and the semiconductor structure further includes a second guard ring structure disposed between the logic circuit region and the first guard ring structure.

In yet another example aspect, the present disclosure provides a method of manufacturing a semiconductor device. The method includes forming first gate stacks in a first circuit region of a substrate, forming second gate stacks in a second circuit region of the substrate, forming a third gate stack in a guard ring region between the first circuit region and the second circuit region, the first gate stacks, the second gate stacks, and the third gate stack each including a same material composition, and the third gate stack fully surrounding the second circuit region in a top view, depositing a patterned mask layer covering the guard ring region and the second circuit region, performing an etching process to remove a first metal fill layer in the first gate stacks, the etching process also partially etching the third gate stack in forming a gap, depositing a second metal fill layer in the second gate stacks and in the gap of the third gate stack, and planarizing the semiconductor device to expose the first metal fill layer in the second gate stacks. In some embodiments, the first metal fill layer and the second metal fill layer include a same metal but with different grain sizes. In some embodiments, the first circuit region is a logic circuit region, and the second circuit region is a radio frequency (RF) circuit region.

The foregoing has outlined features of several embodiments. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A method of manufacturing a semiconductor device, comprising:
forming a plurality of first fins in a first region of the semiconductor device, a plurality of second fins in a second region of the semiconductor device, a plurality of third fins in a third region of the semiconductor device, the second region encircling the first region, the third region encircling the second region;
forming a plurality of first gate stacks over the first fins, a plurality of second gate stacks over the second fins, and a plurality of third gate stacks over the third fins;
forming a mask layer covering the first region and the second region;
performing an etching process to remove at least a portion of the third gate stacks;
depositing a metal-containing material to replace the removed portion of the third gate stacks; and
performing a planarization process to expose the first and second gate stacks.

2. The method of claim 1, wherein the performing of the etching process also removes at least a portion of the second gate stacks.

3. The method of claim 1, wherein the depositing of the metal-containing material also deposits the metal-containing material to replace the removed portion of the second gate stacks.

4. The method of claim 1, wherein prior to the performing of the etching process, the first, second, and third gate stacks include a same gate electrode.

5. The method of claim 4, wherein after the depositing of the metal-containing material, a metal fill layer in the first gate stacks has a different material composition from a metal fill layer in the third gate stacks.

6. The method of claim 5, wherein after the depositing of the metal-containing material, the metal fill layer in the first gate stacks has a larger width than the metal fill layer in the third gate stacks.

7. The method of claim 1, wherein the second gate stacks form a gate stack ring encircling the first region.

8. The method of claim 7, wherein the gate stack ring is a first gate stack ring, wherein the second gate stacks also form a second gate stack ring encircling the first gate stack ring.

9. The method of claim 8, wherein a metal fill layer in the second gate stack ring has a different material composition from a metal fill layer in the first gate stack ring.

10. The method of claim 1, wherein a width of the second fins is larger than a width of the first fins and a width of the third fins.

11. A method of manufacturing a semiconductor device, comprising:
forming first gate stacks in a first circuit region of the semiconductor device, second gate stacks in a second circuit region of the semiconductor device, and a third gate stack in a guard ring region between the first circuit region and the second circuit region, wherein the third gate stack fully surrounds the first circuit region when viewed from top;
performing an etching process to remove a metal fill layer in the second gate stacks, wherein the etching process also etches at least a portion of a metal fill layer in the third gate stack; and
depositing a metal-containing material as a replacement metal fill layer in the second gate stacks, wherein the metal-containing material is also deposited in the third gate stack.

12. The method of claim 11, wherein, prior to the performing of the etching process, the first, second, and third gate stacks include a same material composition.

13. The method of claim 11, wherein the metal-containing material is also deposited in the first circuit region and over the first gate stacks, the method further comprising:
planarizing the semiconductor device to remove the metal-containing material from the first circuit region and expose a metal fill layer in the first gate stacks.

14. The method of claim 11, wherein the metal fill layer in the second gate stacks and the replacement metal fill layer in the second gate stacks include a same metal but with different grain sizes.

15. The method of claim 11, wherein the first circuit region is a radio frequency (RF) circuit region, and the second circuit region is a logic circuit region.

16. The method of claim 11, wherein the guard ring region also includes a fourth gate stack fully surrounding the third gate stack when viewed from top.

17. A semiconductor device, comprising:
first transistors in a first circuit region of the semiconductor device, the first transistors including first gate stacks;
second transistors in a second circuit region of the semiconductor device, the second transistors including second gate stacks, the first and second gate stacks having a same conductivity type, the first and second gate stacks having metal fill layers of different material compositions; and
a gate stack ring disposed between the first circuit region and the second circuit region, the gate stack ring surrounding the first circuit region.

18. The semiconductor device of claim 17, wherein the first transistors are radio frequency (RF) transistors and the second transistors are logic transistors.

19. The semiconductor device of claim 17, wherein the gate stack ring and the first gate stacks have metal fill layers of a same material composition.

20. The semiconductor device of claim 17, wherein the gate stack ring and the second gate stacks have metal fill layers of a same material composition.
